(19) United States
(12) Patent Application Publication
(10) Pub. No.: US 2011/0227141 A1
(43) Pub. Date: Sep. 22, 2011

(54) NON-VOLATILE MEMORY DEVICES HAVING VERTICAL CHANNEL STRUCTURES AND RELATED FABRICATION METHODS

(75) Inventors: Jae-hun Jeong, Hwangsoeng-si (KR); Han-soo Kim, Suwon-si (KR); Won-seok Cho, Suwon-si (KR); Jae-hoon Jang, Seongnam-si (KR)

(73) Assignee: Samsung Electroncis Co., Ltd.

(21) Appl. No.: 13/048,649

(22) Filed: Mar. 15, 2011

(30) Foreign Application Priority Data
Mar. 16, 2010 (KR) 10-2010-0023398

(51) Int. Cl. H01L 29/792

(52) U.S. Cl. 257/324; 257/E29.309

(57) ABSTRACT

A memory device having a vertical channel structure is disclosed. The memory device includes a plurality of gate lines extending substantially parallel to one another along a surface of a substrate, and a connection unit electrically connecting the plurality of gate lines. The connection unit includes a first portion laterally extending along the surface of the substrate, a second portion extending substantially perpendicular to the surface of the substrate, and a supporting insulating layer extending in a cavity defined by the first and second portions of the connection unit. Related fabrication methods are also discussed.

### CROSS-REFERENCE TO RELATED APPLICATIONS

This application claims priority under 35 U.S.C. §119 from Korean Patent Application No. 10-2010-0023398, filed on Mar. 16, 2010, in the Korean Intellectual Property Office, the disclosure of which is incorporated by reference herein in its entirety.

### BACKGROUND

The inventive concept relates to memory devices, and more particularly, to non-volatile memory devices having a vertical channel structure and related methods of fabrication.

Today, electronic products have been developed to be smaller and smaller in size but are nevertheless required to process a large amount of data. Thus, it may be desirable to increase the degree of integration in semiconductor memory devices used in such electronic products. For example, a non-volatile memory device having a vertical transistor structure instead of a flat transistor structure has been proposed in order to improve integration in semiconductor memory devices.

### SUMMARY

Embodiments of the inventive concept provide a non-volatile memory device having a vertical channel structure, in which multi-layered gate lines may be connected to an external circuit.

According to some embodiments of the inventive concept, a memory device includes a plurality of gate lines extending substantially parallel to one another along a surface of a substrate, and a connection unit electrically connecting the plurality of gate lines. The connection unit includes a first portion laterally extending along the surface of the substrate, a second portion extending substantially perpendicular to the surface of the substrate, and a supporting insulating layer extending in a cavity defined by the first and second portions of the connection unit.

In some embodiments, the supporting insulating layer may include a first portion extending substantially parallel to the surface of the substrate and a second portion extending substantially perpendicular to the surface of the substrate within the cavity.

In some embodiments, the plurality of gate lines and the connection unit may be provided between first and second insulating layers. The first insulating layer may include a first portion extending along the surface of the substrate and having the plurality of gate lines and the first portion of the connection unit thereon, and a second portion extending substantially perpendicular to the surface of the substrate and having the second portion of the connection unit on a sidewall thereof. The second insulating layer may be provided on the plurality of gate lines and the connection unit, and may include a first portion extending along the plurality of gate lines and the first portion of the connection unit, and a second portion extending substantially perpendicular to the surface of the substrate and along a sidewall of the second portion of the connection unit. The first and second insulating layers may further define the cavity including the supporting insulating layer therein.

In some embodiments, the first and second insulating layers may be a different material than the supporting insulating layer.

In some embodiments, the substrate may include a device region including the plurality of gate lines thereon and a connection region including the connection unit thereon adjacent thereto. A plurality of semiconductor poles may extend substantially perpendicular to the surface of the substrate in the device region. Each of the plurality of semiconductor poles may include a respective memory cell string comprising a plurality of memory cells extending along a sidewall thereof. Each of the plurality of gate lines may extend on the sidewall of a different one of the plurality of semiconductor poles, and may define a word line of the respective memory cell string thereon.

In some embodiments, the plurality of gate lines, the connection unit, and the supporting insulating layer may respectively comprise a first plurality of gate lines, a first connection unit, and a first supporting insulating layer. A second plurality of gate lines may extend substantially parallel to one another along the first portion of the second insulating layer, and each of the second plurality of gate lines may extend on a sidewall of a different one of the plurality of semiconductor poles.

In some embodiments, each of the second plurality of gate lines may define a word line of the respective memory cell string. A second connection unit may electrically connect the second plurality of gate lines. The second connection unit may include a first portion extending along the first portion of the second insulating layer, a second portion extending along a sidewall of the second portion of the second insulating layer substantially perpendicular to the surface of the substrate, and a second supporting insulating layer extending in a cavity defined by the first and second portions of the second connection unit and the second insulating layer.

In some embodiments, the first supporting insulating layer and the second supporting insulating layer may be a same material.

In some embodiments, each of the second plurality of gate lines may define a string select line of the respective memory cell string. A cover insulating layer may extend on the second plurality of gate lines, and a surface of the cover insulating layer may be below an uppermost surface of the second portion of the first insulating layer.

In some embodiments, a thickness of the second portion of the first insulating layer may be greater than that of the second portion of the second insulating layer.

In some embodiments, a thickness of the first portion of the first insulating layer may be less than that of the first portion of the second insulating layer.

According to further embodiments of the inventive concept, a method of fabricating a memory device includes forming a plurality of gate lines extending substantially parallel to one another along a surface of a substrate; and forming a connection unit electrically connecting the plurality of gate lines. The connection unit includes a first portion laterally extending along the surface of the substrate, a second portion extending substantially perpendicular to the surface of the substrate, and a supporting insulating layer extending in a cavity defined by the first and second portions of the connection unit.

In some embodiments, the supporting insulating layer may include a first portion extending substantially parallel to the surface of the substrate and a second portion extending substantially perpendicular to the surface of the substrate within the cavity.

In some embodiments, the plurality of gate lines and the connection unit may be formed by sequentially forming a first insulating layer, a sacrificial layer, and a second insulating layer, each including a first portion extending along the surface of the substrate and a second portion extending substantially perpendicular to the surface of the substrate. Portions of the sacrificial layer between the first and second insulating layers may be selectively removed to define a plurality of first grooves extending substantially parallel along the first portion of the first insulating layer, and a second groove extending along the second portion of the first insulating layer substantially perpendicular to the plurality of first grooves. Remaining portions of the sacrificial layer between the plurality of first grooves and the second groove may provide support for the first and second insulating layers and may define the supporting insulating layer. A conductive layer may be formed in the plurality of first grooves to define the plurality of gate lines and the first portion of the connection unit, and in the second groove to define the second portion of the connection unit.

In some embodiments, a plurality of channel holes may be formed extending through the second insulating layer, the sacrificial layer, and the first insulating layer to expose the substrate. A plurality of semiconductor poles may be formed to extend substantially perpendicular to the surface of the substrate in the plurality of channel holes. Each of the plurality of semiconductor poles may include a respective memory cell string having a plurality of memory cells extending along a sidewall thereof. Each of the plurality of gate lines may extend on the sidewall of a different one of the plurality of semiconductor poles, and each of the plurality of gate lines may define a word line of the respective memory cell string thereon.

According to still further embodiments of the inventive concept, a non-volatile memory device includes a substrate having a main surface extending in a first direction, wherein a device region and a connection region are defined in the substrate; a plurality of semiconductor poles extending in a second direction perpendicular to the first direction in the device region; a plurality of NAND cell strings extending along sidewalls of the plurality of semiconductor poles, where each of the plurality of NAND cell strings includes a plurality of memory cells; a plurality of gate lines defining word lines of the plurality of memory and extending in the first direction in the device region; and a gate connection structure including a plurality of conductive gate connection units in the connection region, where each of the plurality of conductive gate connection units includes a horizontal part connected to the plurality of gate lines and extending in the first direction, and a pillar part connected to the horizontal part and extending in the second direction, wherein each of the plurality of gate connection units includes an aperture that is formed in a space defined by the corresponding horizontal part and pillar part, and wherein the aperture includes a supporting insulating layer therein.

Upper and lower surfaces of the supporting insulating layer may be at same levels as upper and lower surfaces of the plurality of gate connection units, respectively.

The non-volatile memory device may further include a first interlevel insulating layer disposed between the plurality of gate connection units. The first interlevel insulating layer may be formed of a different material than that of the supporting insulating layer.

Each of the plurality of NAND cell strings may further include a lower selection transistor and an upper selection transistor having the plurality of memory cells therebetween, a plurality of lower gate lines forming the lower selection transistor and extending in the first direction; and a lower gate connection unit formed in the connection region and formed of a conductive material, the lower gate connection unit including a lower horizontal part that is connected to the plurality of lower gate lines and extends in the first direction, and a lower pillar part that is connected to the lower horizontal part and extends in the second direction. The lower gate connection unit may include a lower aperture formed in a space defined by the lower horizontal part and the lower pillar part, and a lower supporting insulating layer in the lower aperture.

The supporting insulating layer and the lower supporting insulating layer may be formed of the same material.

The non-volatile memory device may further include a plurality of upper gate lines forming the upper selection transistor and extending in the first direction; and a plurality of upper gate connection units formed of a conductive material in the connection region and connected to the plurality of upper gate lines, respectively. Each of the plurality of upper gate connection units may include an upper horizontal part extending in the first direction, and an upper pillar part connected to the upper horizontal part and extending in the second direction.

The non-volatile memory device may further include a second interlevel insulating layer disposed between the plurality of upper gate connection units and the gate connection unit group. A second thickness of the second interlevel insulating layer from the upper pillar part in the first direction may be greater than a first thickness of the first interlevel insulating layer from the pillar part in the first direction.

The non-volatile memory device may further include a third interlevel insulating layer disposed between the lower gate connection unit and the gate connection structure. A third thickness of the third interlevel insulating layer from the lower pillar part in a direction opposite to the first direction, may be less than the second thickness of the second interlevel insulating layer.

The non-volatile memory device may further include a fourth interlevel insulating layer disposed between gate lines forming the memory cells of a NAND cell string selected from among the plurality of NAND cell strings. The first interlevel insulating layer and the fourth interlevel insulating layer may be formed of the same material.

The plurality of gate connection units may be connected to ones of the plurality of gate lines at same levels with respect to the substrate.

The horizontal part may be disposed between the plurality of gate lines and the pillar part.

Pillar connection units of the pillar part, which extend from the apertures in the second direction, may be formed of a different material from a material of the horizontal part.

The non-volatile memory device may further include contact plugs that are formed on the pillar part and are used for connection to an external circuit.

A tunneling insulating layer, a charge storing layer, and a blocking insulating layer may further be disposed between the semiconductor poles and the plurality of gate lines.

Upper and lower surfaces of the horizontal part may be at a same level as the plurality of gate lines connected thereto.

Sides of the apertures of the plurality of gate connection units, which are adjacent to the device region, may be arranged in the second direction.

Sides of the apertures of the plurality of gate connection units in the second direction may be arranged in the first direction.

The more the horizontal parts of the plurality of gate connection units are closer to the substrate, the longer the horizontal parts may be in the first direction.

The gate connection unit may have a same thickness as the plurality of gate lines connected thereto.

The non-volatile memory device may further include upper contact plugs that are formed on the upper pillar parts included in the plurality of the upper gate connections units, respectively, and may be used for connection to an external circuit.

### BRIEF DESCRIPTION OF THE DRAWINGS

Exemplary embodiments of the inventive concept will be more clearly understood from the following detailed description taken in conjunction with the accompanying drawings in which:

FIG. 1 is a layout diagram of a memory cell array of a non-volatile memory device having a vertical channel structure, according to an embodiment of the inventive concept;

FIGS. 2 to 16 are views illustrating a structure of and a method of fabricating a non-volatile memory device according to an embodiment of the inventive concept;

FIGS. 17A to 24 are views illustrating a structure of and a method of fabricating a non-volatile memory device according to another embodiment of the inventive concept;

FIG. 25 is a schematic block diagram of a non-volatile memory device according to another embodiment of the inventive concept;

FIG. 26 is a schematic block diagram of a memory card according to an embodiment of the inventive concept; and

FIG. 27 is a schematic block diagram of an electronic system according to an embodiment of the inventive concept.

### DETAILED DESCRIPTION OF THE DRAWINGS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to,” “directly coupled to,” or “in direct contact with” another element or layer, there are no intervening elements or layers present. Other expressions for describing relationships between elements, for example, “between” and “immediately between” or “neighboring” and “directly neighboring” may also be understood likewise.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. As used herein, the term “and/or” includes any and all combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the inventive concept will be described in detail with reference to the accompanying drawings.

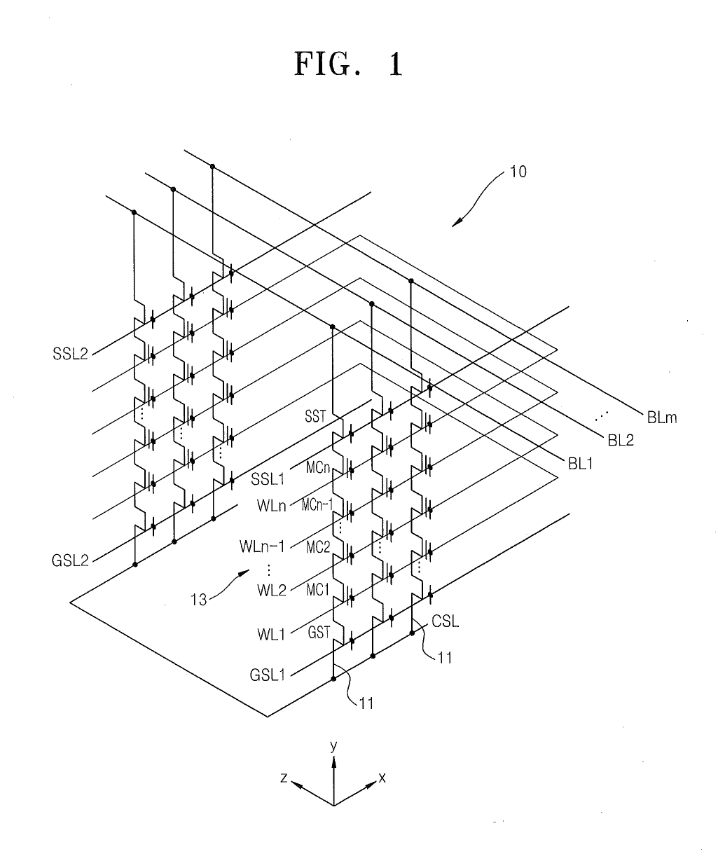

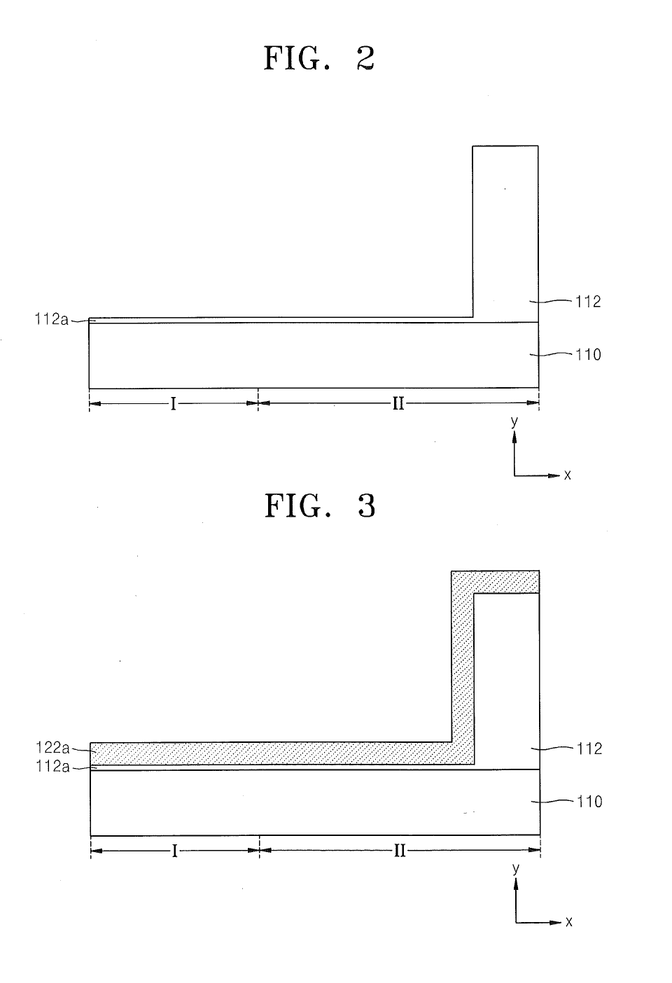

FIG. 1 is a layout diagram of a memory cell array 10 of a non-volatile memory device having a vertical channel structure according to an embodiment of the inventive concept. Referring to FIG. 1, the memory cell array 10 may be a NAND type that includes a plurality of NAND cell strings 11. The NAND cell strings 11 may be arranged in a matrix of rows and columns. A memory cell block 13 may include a plurality of NAND cell strings 11 arranged in the same column, e.g., in an x-axis direction, and/or the same row, e.g., in a z-axis direction.

Each of the NAND cell strings 11 may include a plurality of memory cells MC1 to MCn, an upper selection transistor (string selection transistor) SST, and a lower selection transistor (ground selection transistor) GST. The memory cells MC1 to MCn, the string selection transistor SST, and the ground selection transistor GST that constitute each of the NAND cell strings 11 may be arranged in series to be perpendicular to the z-axis direction.

One side, e.g., drains of the string selection transistors SST, of the NAND cell strings 11 arranged on the memory cell block 13 may be connected to bit lines BL1 to BLm. Another side, e.g., sources of the ground selection transistors GST, of the NAND cell strings 11, may be connected commonly to a common source line CSL.

The memory cells MC1 to MCn may be arranged in series to be perpendicular between the corresponding string selection transistor SST and ground selection transistor GST. Gates of memory cells arranged on the same layer from among the memory cells MC1 to MCn may be connected commonly to word lines WL1 to WLn. Data stored in the memory cells MC1 to MCn may be programmed, read or erased by driving the word lines WL1 to WLn.

The string selection transistors SST may be arranged between the bit lines BL1 to BLm and the respective memory cells MCn of each string 11. The string selection transistors SST arranged on the memory cell block 13 may control exchange of data between the bit lines BL1 to BLm and the memory cells MC1 to MCn via upper selection lines (string selection lines) SSL1 or SSL2 connected to gates of the string selection transistors SST.

The ground selection transistors GST may be arranged between the respective memory cells MC1 of each string 11 and the common source line CSL. The ground selection transistors GST arranged on the memory cell blocks 13 may control exchange of data between the memory cells MC1 to MCn and the common source line CSL via lower selection lines (ground selection lines) GSL1 or GSL2 connected to gates of the ground selection transistors GST.

A structure of and a method of fabricating the memory cell array 10 of FIG. 1 according to an embodiment of the inventive concept will now be described in detail. For convenience of explanation, the memory cell array 10 will be described focusing on the memory cells MC1 to MCn, the string selection transistors SST, and the ground selection transistors GST of the NAND cell strings 11, the word lines MC1 to MCn, the string selection lines SSL1 and SSL2, and the ground selection lines GSL1, and the GSL2. Other elements of the memory cell array 10 may be described briefly or may not be described herein, and other elements may be included in the memory cell array 10.

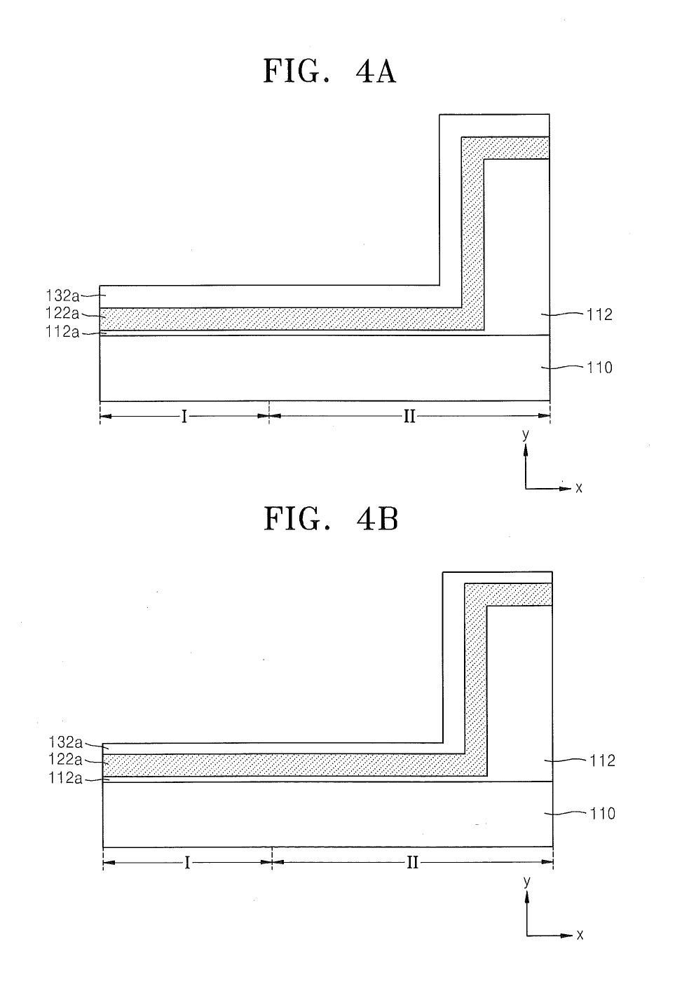

FIGS. 2 to 16 are views illustrating a structure of and a method of fabricating a non-volatile memory device 100 according to an embodiment of the inventive concept. FIG. 2 is a cross-sectional view illustrating a process of forming an insulating pillar 112 according to an embodiment of the inventive concept. Referring to FIG. 2, the insulating pillar 112 is formed on a substrate 110 having a main surface extending in a first direction (x-axis direction). The substrate 110 may be formed of a semiconductor material, e.g., a IV-group semiconductor, III-V group compound semiconductors, or II-VI group oxide semiconductors. For example, the IV-group semiconductor may include silicon, germanium, or silicon-germanium. The substrate 110 may be provided in the form of bulk wafer or epitaxial layer.

In the substrate 110, a device region I and a connection region II may be defined. In the device region I, NAND cell strings may be formed. In the connection region II, gate connection units will be formed so as to connect word lines, i.e., gate lines, which are connected to the NAND cell strings to form memory cells MC1 to MCn as shown in FIG. 1, to an external circuit. The insulating pillar 112 may be formed in the connection region II of the substrate 110 to extend in a second direction (y-axis direction) perpendicular to the first direction (x-axis direction). In particular, the insulating pillar 112 may be formed on the connection region II to be spaced a predetermined distance apart from the device region I. The gate connection units may be formed on a space between the insulating pillar 112 and the device region I.

A base insulating layer 112a may be formed separately or together with the insulating pillar 112 to extend to the device region I from a side surface of the insulating pillar 112. That is, the base insulating layer 112a may be formed after the insulating pillar 112 is formed or the insulating pillar 112 may be formed after the base insulating layer 112a is formed. For example, if the base insulating layer 112a is formed after the insulating pillar 112 is formed, the base insulating layer 112a may be foamed to cover both the substrate 110 in the device region I and the connection region II and the insulating pillar 112. However, since the base insulating layer 112a is relatively thinner than the insulating pillar 112, the portion of the base insulating layer 112a formed on the insulating pillar 112 may be regarded as a portion of the insulating pillar 112. Thus, the base insulating layer 112a may be formed only on a portion of the substrate 110, in which the insulating pillar 112 is not formed.

The insulating pillar 112 and the base insulating layer 112a may be formed of different insulating materials, or may be formed of the same insulating material. For example, the insulating pillar 112 and the base insulating layer 112a may be formed of an oxide.

FIG. 3 is a cross-sectional view illustrating a process of forming a first preliminary sacrificial layer 122a according to an embodiment of the inventive concept. Referring to FIG. 3, the first preliminary sacrificial layer 122a is formed on the insulating pillar 112 and the base insulating layer 112a. The first preliminary sacrificial layer 122a may be formed to cover upper and side surfaces of the insulating pillar 112 and an upper surface of the base insulating layer 112a. The first preliminary sacrificial layer 122a may be formed of a material having a different etch selectivity from those of the insulating pillar 112 and the base insulating layer 112a. For example, the insulating pillar 112 and the base insulating layer 112a may include an oxide, and the first preliminary sacrificial layer 122a may include a nitride.

The first preliminary sacrificial layer 122a may be formed to the same thickness on all the upper and side surfaces of the insulating pillar 112 and the upper surface of the base insulating layer 112a. However, the first preliminary sacrificial layer 122a may be formed in such a way that it has different thicknesses on the side surface of the insulating pillar 112 and on the upper surfaces of the insulating pillar 112 and base insulating layer 112a, similar to a process, e.g., an etch-back process, which will be described with reference to FIG. 4B.

FIG. 4A is a cross-sectional view illustrating a process of forming a first preliminary insulating layer 132a according to an embodiment of the inventive concept. Referring to FIG. 4A, the first preliminary insulating layer 132a is formed on the first preliminary sacrificial layer 122a. The first preliminary insulating layer 132a may be formed to completely cover an upper surface of the first preliminary sacrificial layer 122a. The first preliminary insulating layer 132a may also be formed to have the same thickness over the first preliminary sacrificial layer 122a, i.e., on a lower upper surface of the first preliminary sacrificial layer 122a, which extends from the device region I to a portion of the connection region II, an upper surface of the first preliminary sacrificial layer 122a in the connection region II, and an upper side surface of the first preliminary sacrificial layer 122a that connects the lower upper surface with the upper surface. The first preliminary insulating layer 132a may be formed of a material having a different etch selectivity from that of the first preliminary sacrificial layer 122a. For example, the first preliminary sacrificial layer 122a may include a nitride, and the first preliminary insulating layer 132a may include an oxide.

FIG. 4B is a cross-sectional view illustrating a process of etching back the first preliminary insulating layer 132a, according to another embodiment of the inventive concept. Referring to FIG. 4B, the first preliminary insulating layer 132a may be removed partially according to the etch-back process. Thus, portions of the first preliminary insulating layer 132a which extend in the first direction (x-axis direction) may be thinner than a portion of the first preliminary insulating layer 132a which extends in the second direction (y-axis direction). The etching back of the first preliminary insulating layer 122a may be performed optionally in case that the portion of the first preliminary insulating layer 132a extending in the second direction (y-axis direction) needs to be thick enough to form contact plugs for connection to an external circuit (not shown) in a subsequent process.

Also, although not described herein, the etch-back process may also be performed on the first preliminary sacrificial layer 122a.

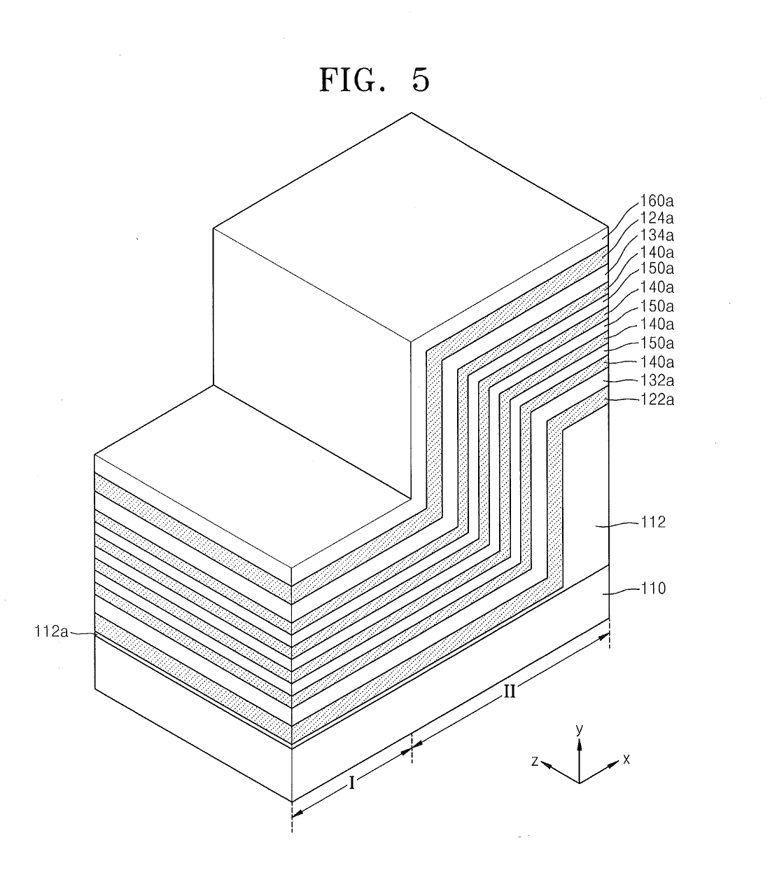

FIG. 5 is a perspective view illustrating a process of forming other preliminary insulating layers and other preliminary sacrificial layers, according to an embodiment of the inventive concept. Referring to FIG. 5, a plurality of second preliminary sacrificial layers 140a and a plurality of second preliminary insulating layers 150a may be alternately stacked, and a third preliminary insulating layer 134a and a third preliminary sacrificial layer 124a may be further formed on the resultant structure, similar to the processes of forming the first preliminary sacrificial layer 122a and the first preliminary insulating layer 132a, which were described above with reference to FIGS. 3 and 4A. Each of the plurality of second preliminary insulating layers 150a may be disposed between two adjacent second preliminary sacrificial layers 140a. Thus, the total number of the plurality of second preliminary insulating layers 150a may be less by one than that of the plurality of second preliminary sacrificial layers 140a.

The plurality of second preliminary sacrificial layers 140a may be formed of a material having a different etch selectivity from that of the plurality of second preliminary insulating layers 150a. The third preliminary sacrificial layer 124a may also be formed of a material having a different etch selectivity from that of the third preliminary insulating layer 134a. The first to third preliminary sacrificial layers 122a, 140a, and 124a may be formed of materials having the similar etch selectivity, respectively, or may be formed of the same material. Also, the first to third preliminary insulating layers 132a, 150a, and 134a may be formed of materials having the similar etch selectivity, respectively, or may be formed of the same material. However, the first to third preliminary sacrificial layers 122a, 140a, and 124a may be formed of a material having a different etch selectivity from that of the first to third preliminary insulating layers 132a, 150a, and 134a. For example, the first to third preliminary sacrificial layers 122a, 140a, and 124a may include a nitride, and the first to third preliminary insulating layers 132a, 150a, and 134a may include an oxide.

The number of the plurality of second preliminary sacrificial layers 140a is not limited to the number of layers shown in FIG. 5. The more second preliminary sacrificial layers 140a, the more memory cells per unit area.

A preliminary cover insulating layer 160a may be formed on the third preliminary sacrificial layer 124a. At least a portion of the preliminary cover insulating layer 160a in the device region I may be located at the same level as a portion of the insulating pillar 112 with respect to the substrate 110. That is, an upper surface of a portion of the preliminary cover insulating layer 160a in the device region I may be located at a lower level than the upper surface of the insulating pillar 112 with respect to the substrate 110, or a lowest surface of the preliminary cover insulating layer 160a may be located at a lower level than the upper surface of the insulating pillar 112 with respect to the substrate 110.

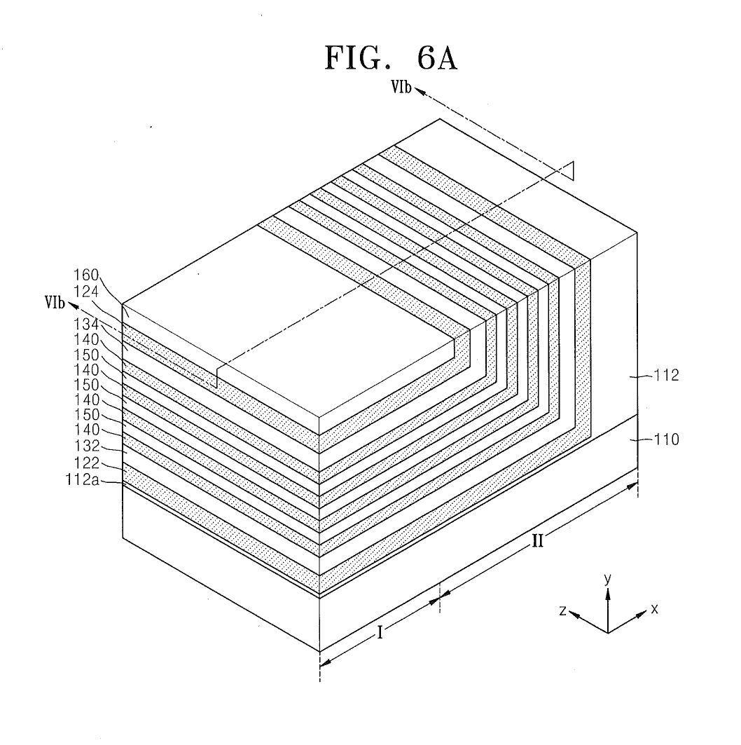

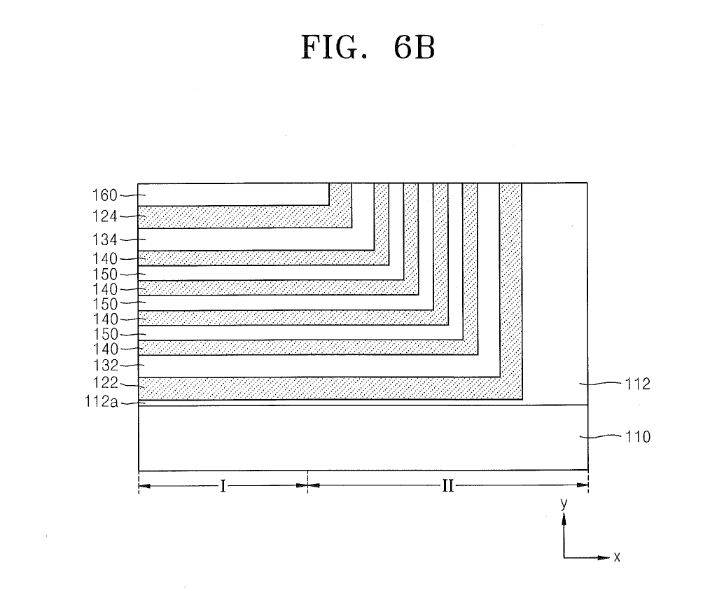

Although not shown, the processes described above with reference to FIGS. 2 to 5 may also be performed simultaneously in a direction (negative x-axis direction) opposite to the first direction (x-axis direction). Thus, a plane that is symmetrical to and same in shape as the yz plane formed by the second direction (y-axis direction) and a third direction (z-axis direction) may be formed. This may be applied to processes that will be described with reference to FIGS. 6A to 24.

FIGS. 6A and 6B illustrate a process of forming first to third sacrificial layers 122, 140, and 124, first to third insulating layers 132, 150, and 134, and a cover insulating layer 160, according to an embodiment of the inventive concept. In detail, FIG. 6A is a perspective view illustrating a process of forming the first to third sacrificial layers 122, 140, and 124, the first to third insulating layers 132, 150, and 134, and the cover insulating layer 160, according to an embodiment of the inventive concept. Referring to FIGS. 5 and 6A, the first to third sacrificial layers 122, 140, and 124, the first to third insulating layers 132, 150, and 134, and the cover insulating layer 160 are formed by partially removing the first to third preliminary sacrificial layers 122a, 140a, and 124a, the first to third preliminary insulating layers 132a, 150a, and 134a, and the preliminary cover insulating layer 160a until the insulating pillar 112 is exposed. In this case, the cover insulating layer 160 may prevent the third sacrificial layer 124 from being exposed in the device region I.

Consequently, the first to third sacrificial layers 122, 140, and 124 and the first to third insulating layers 132, 150, and 134 may have an L-shaped structure extending in the third direction (z-axis direction). The third direction (z-axis direction) is perpendicular to both the first direction (x-axis direction) and the second direction (y-axis direction).

FIG. 6B is a cross-sectional view illustrating a process of forming the first to third sacrificial layers 122, 140, and 124, the first to third insulating layers 132, 150, and 134, and the cover insulating layer 160, according to an embodiment of the inventive concept. In detail, FIG. 6B is a cross-sectional view taken along the line VIb-VIb of FIG. 6A. Referring to FIG. 6B, the first to third sacrificial layers 122, 140, 124 and the first to third insulating layers 132, 150, 134 may be L-shaped structures extending in the third direction (z-axis direction). That is, the first sacrificial layer 122, the first insulating layer 132, a plurality of second sacrificial layers 140 and a plurality of second insulating layers 150 that are alternately arranged, the third insulating layer 134, and the third sacrificial layer 124 may be L-shaped structures that overlap with one another. The pointed portions of the L-shaped structures may be located in the connection region II.

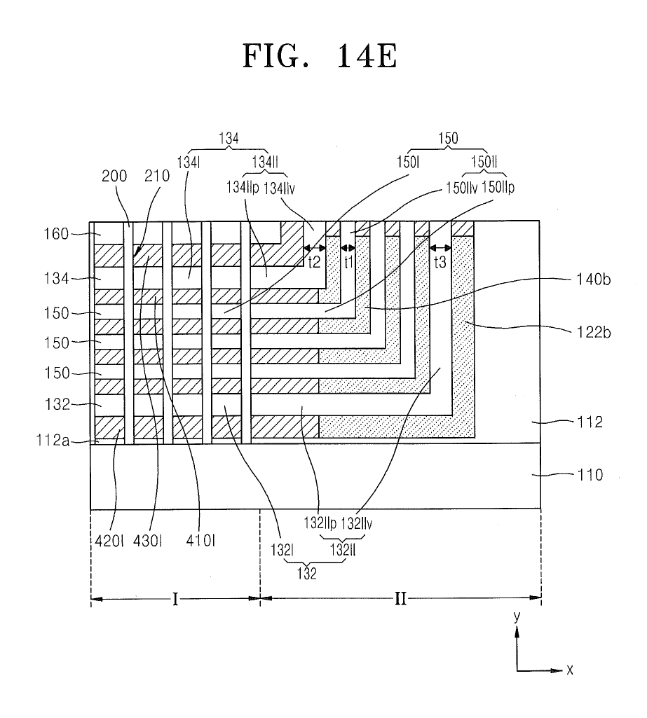

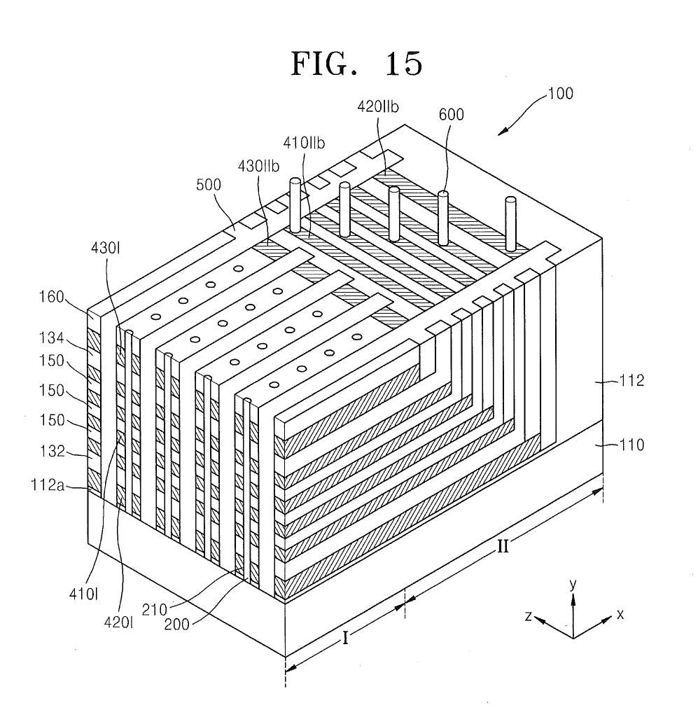

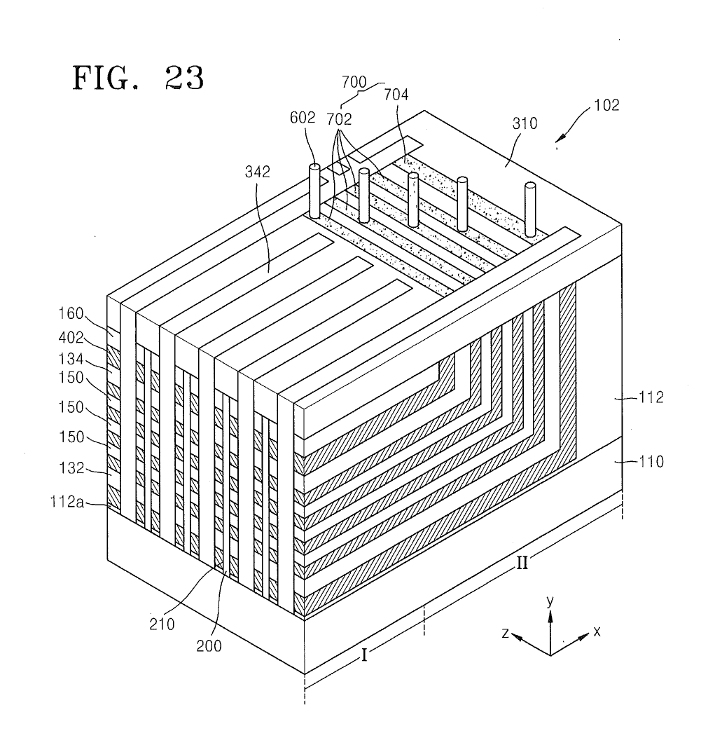

Although in FIGS. 6A and 6B and the subsequent figures the thicknesses of the second sacrificial layer 140 and second insulating layer 150 are illustrated to be less than those of the first and third sacrificial layers 122 and 124 and the first and third insulating layers 132 and 134 for convenience of explanation, the inventive concept is not limited thereto unless mentioned otherwise. The thicknesses of the first to third sacrificial layers 122, 140, and 124 and the first to third insulating layers 132, 150, and 134 may be determined in consideration of desired features of the non-volatile memory device 100 as shown in FIG. 15 or the non-volatile memory device 102 as shown in FIG. 23 or a method of forming of contact plugs which are used for connection to an external circuit (not shown). However, the plurality of second sacrificial layers 140 may have almost same thickness. The third insulating layer 134 may be thicker than the first and second insulating layers 132 and 150.

Also, although in FIGS. 6A and 6B and the subsequent figures, portions of the first to third sacrificial layers 122, 140, and 124 and the first to third insulating layers 132, 150, and 134 which extend in the first direction (x-axis direction) are illustrated to have almost same thickness as portions which extend in the second direction (y-axis direction) for convenience of explanation, the inventive concept is not limited thereto unless mentioned otherwise.

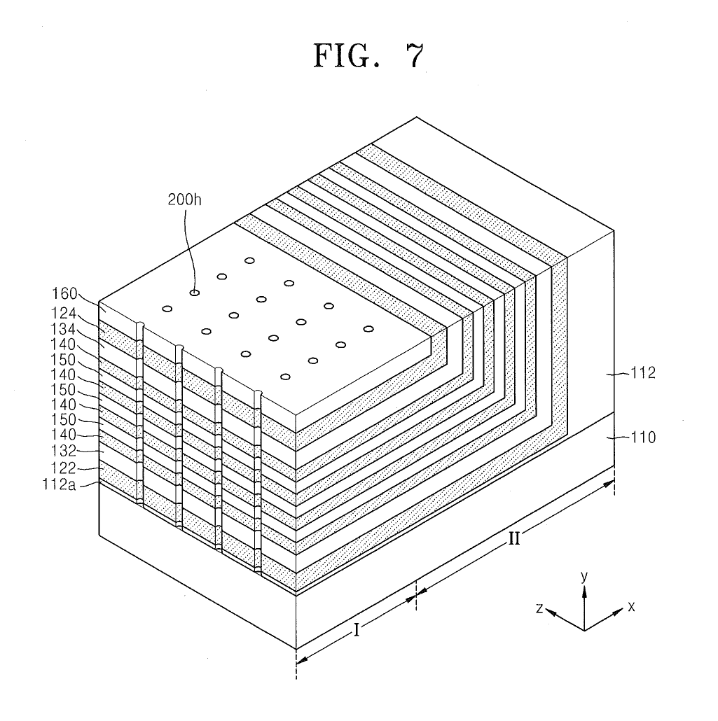

FIG. 7 is a perspective view illustrating a process of forming a plurality of channel holes 200h according to an embodiment of the inventive concept. Referring to FIG. 7, the plurality of channel holes 200h are formed in the device region I to expose the upper surface of the substrate 110 by etching the first to third sacrificial layers 122, 140, and 124, the first to third insulating layers 132, 150, and 134, the base insulating layer 112a, and the cover insulating layer 160 according to a photolithography process.

The plurality of channel holes 200h may be arranged at predetermined intervals in the first direction (x-axis direction) and the third direction (z-axis direction). That is, the plurality of channel holes 200h may be arranged in a matrix of columns and rows. Only some of the plurality of channel holes 200h arranged at the predetermined intervals in the first direction (x-axis direction) are illustrated in the drawings for convenience of explanation. The number of the plurality of channel holes 200h arranged at the predetermined intervals in the first direction (x-axis direction) may be determined according to a size of a minimum cell array of the non-volatile memory device 100 to be fabricated. In the drawings, the number of the plurality of channel holes 200h arranged at the predetermined intervals in the third direction (z-axis direction) is four but the inventive concept is not limited thereto. Channel holes 200h formed in both ends of the device region I are located closest to the border of a minimum cell array of the non-volatile memory device 100 as shown in FIG. 15 or the non-volatile memory device 102 as shown in FIG. 23 from among the plurality of channel holes 200h arranged at the predetermined intervals in the third direction (z-axis direction).

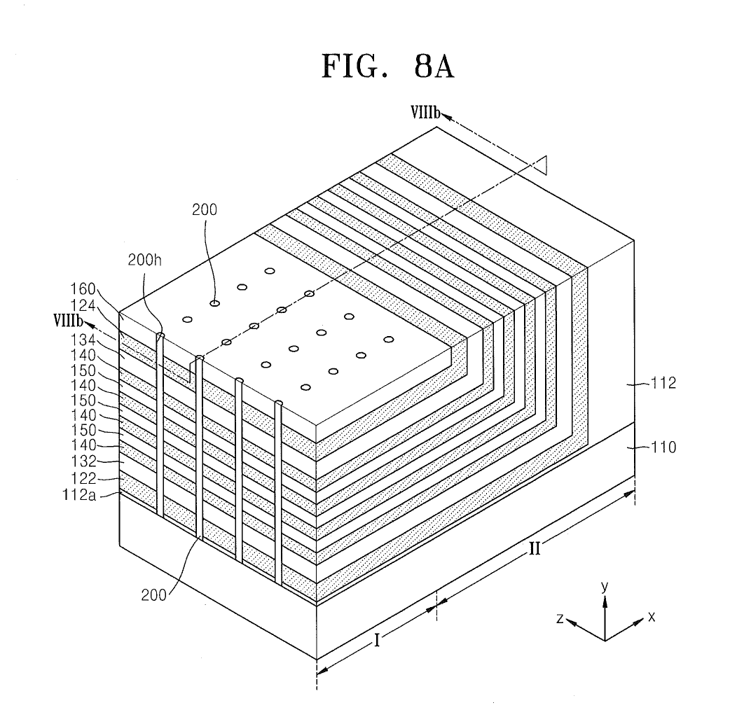

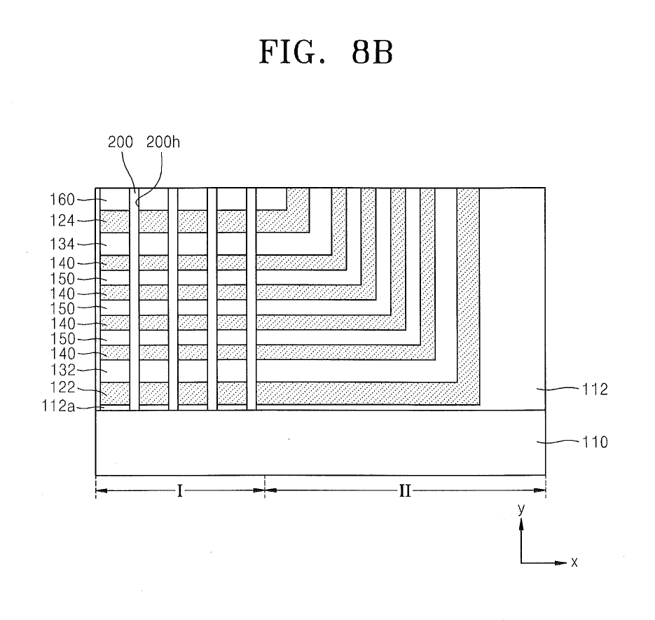

FIGS. 8A and 8B are perspective and cross-sectional views illustrating a process of forming a plurality of semiconductor poles 200, according to an embodiment of the inventive concept. In detail, FIG. 8B is a cross-sectional view taken along the line VIIIb-VIIIb of FIG. 8A. Referring to FIGS. 8A and 8B, the plurality of semiconductor poles 200 are formed to fill the plurality of channel holes 200h therewith. In order to form the plurality of semiconductor poles 200, a semiconductor material is applied onto the resultant structure so that the plurality of channel holes 200h are filled with the semiconductor material, and then the semiconductor material covering the first to third sacrificial layers 122, 140, and 124, the first to third insulating layers 132, 150, and 134, the cover insulating layer 160, and the insulating pillar 112 is partially removed. Chemical mechanical polishing (CMP) or the etch-back process may be performed to partially remove the semiconductor material until the first to third sacrificial layers 122, 140, and 124, the first to third insulating layers 132, 150, and 134, the cover insulating layer 160, and the insulating pillar 112 are exposed, thereby forming the plurality of semiconductor poles 200 for filling the inside of the plurality of channel holes 200h. Thus, the semiconductor poles 200 contact the substrate 110 and extend in the second direction (y-axis direction) perpendicular to the substrate 100.

For example, the semiconductor poles 200 may be formed of silicon or may be formed of polycrystalline or monocrystalline Si epitaxial film. The semiconductor pole 200 may act as channel regions of the NAND cell strings 11 of FIG. 1.

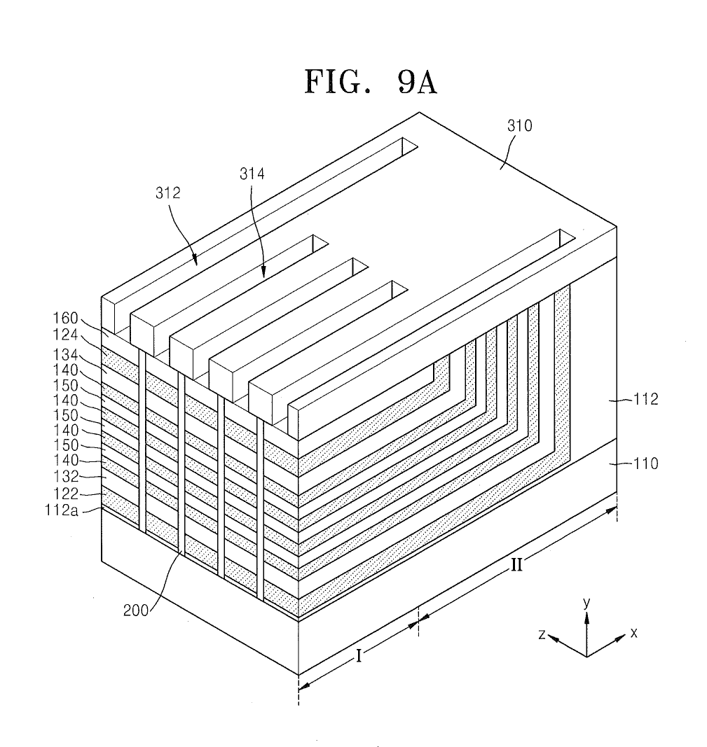

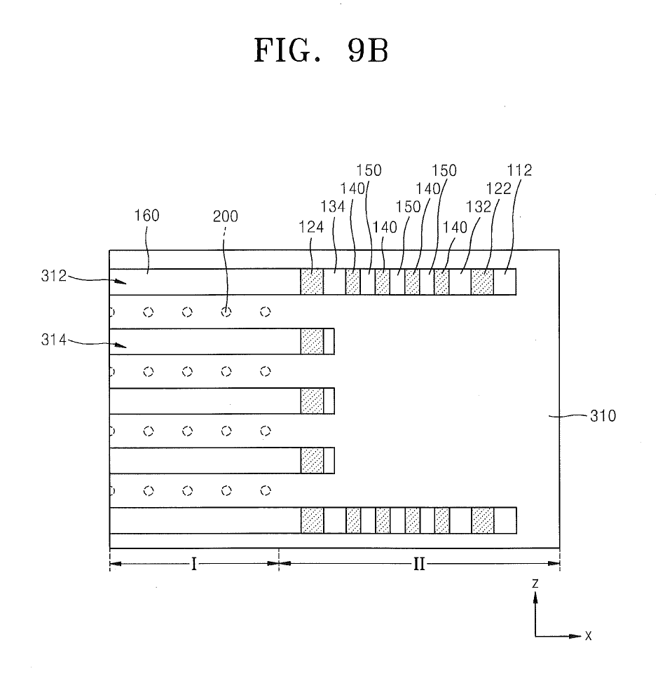

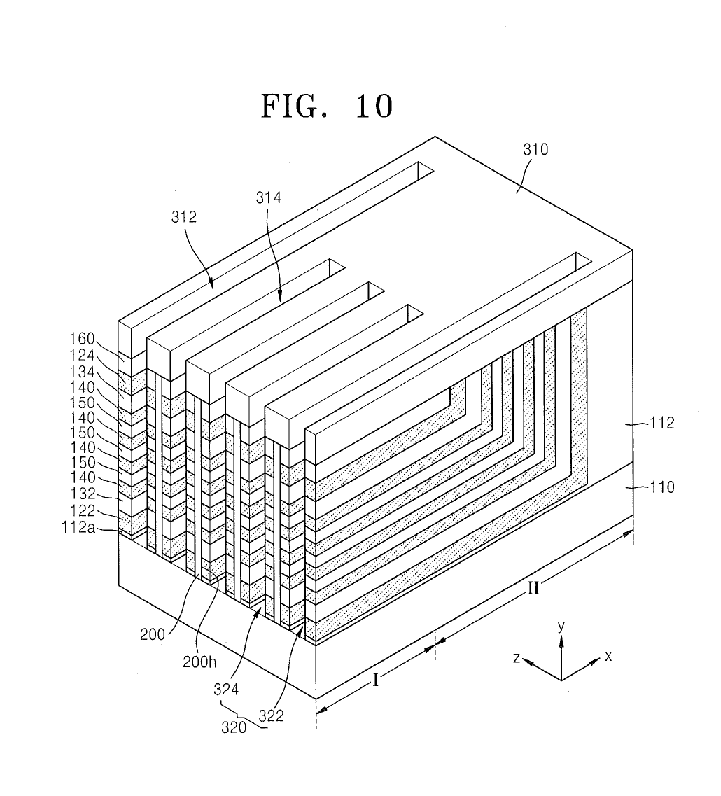

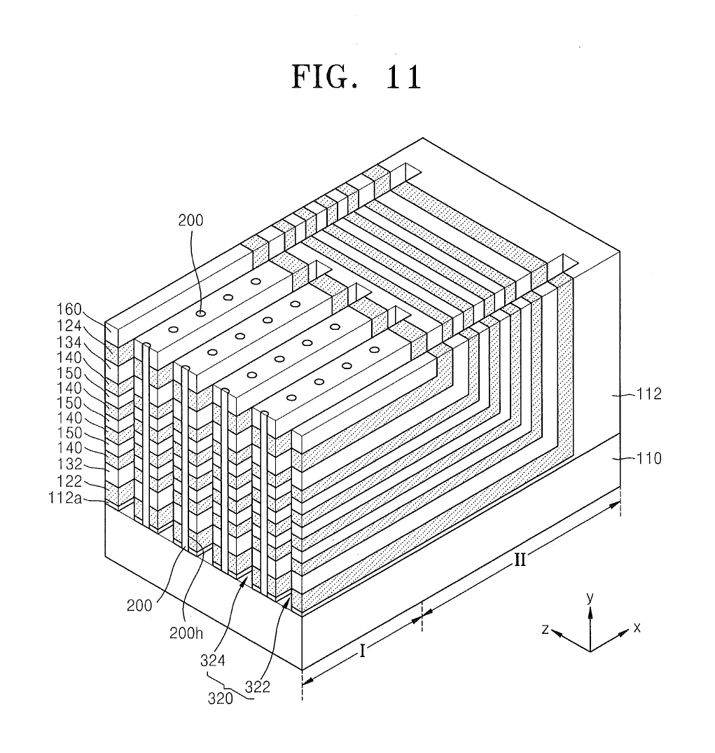

FIGS. 9A and 9B are perspective and plan views illustrating a process of forming a mask pattern 310 according to an embodiment of the inventive concept. In detail, FIG. 9B is a plan view of the mask pattern 310 of FIG. 9A that faces the substrate 110. Referring to FIG. 9A, the mask pattern 310 is formed on the first to third sacrificial layers 122, 140, and 124, the first to third insulating layers 132, 150, and 134, the cover insulating layer 160, and the insulating pillar 112. The mask pattern 310 includes a plurality of linear spaces or grooves 312 and 314 extending in the first direction (x-axis direction). The widths of the linear spaces 312 and 314 in the third direction (z-axis direction) may be greater than the thicknesses of the first to third sacrificial layers 122, 140, and 124.

Referring to FIG. 9B, the mask pattern 310 includes the plurality of linear spaces 312 and 314 extending in the first direction (x-axis direction), and the plurality of linear spaces 312 and 314 are formed in such a manner that the semiconductor poles 200 are not exposed. The mask pattern 310 may be a photoresist pattern or a hard mask pattern.

From among the plurality of linear spaces 312 and 314, two linear spaces 312 formed in both ends of the mask pattern 310 in the third direction (z-axis direction) (hereinafter referred to as long linear spaces 312), extend to be longer than the other linear spaces 314 (hereinafter referred to as short linear spaces 314) in the first direction (x-axis direction). That is, the two long linear spaces 312 may extend starting from the device region I until the upper surface of the insulating pillar 112 is exposed partially in the connection region II, whereas the short linear spaces 314 may extend starting from the device region I until the third sacrificial layer 124 and the third insulating layer 134 are exposed partially in the connection region II. However, the short linear spaces 314 are formed in such a manner that the insulating pillar 112, the first and second sacrificial layers 132 and 140 and the first and second insulating layers 122 and 150 are not exposed.

The short linear spaces 314 extend between rows of adjacent semiconductor poles 200 in the first direction (x-axis direction). The long linear spaces 312 are present between and outside regions, where the semiconductor poles 200 are disposed, respectively, in the third direction (z-axis direction). The long linear spaces 312 extend in the first direction (x-axis direction).

FIG. 10 is a perspective view illustrating a process of forming a plurality of first apertures or grooves 320 according to an embodiment of the inventive concept. Referring to FIGS. 9A, 9B, and 10, the plurality of first apertures 320 are formed by anisotropic-etching the first to third sacrificial layers 122, 140, and 124, the first to third insulating layers 132, 150, and 134, the base insulating layer 112a, and the cover insulating layer 160 by using the mask pattern 310 as an etch mask until an upper surface of the substrate 110 is exposed. The width of the first apertures 320 in the third direction (z-axis direction) may be greater than the thicknesses of the first to third sacrificial layers 122, 140, and 124.

FIG. 11 is a perspective view illustrating a process of removing the mask pattern 310 according to an embodiment of the inventive concept. Referring to FIGS. 10 and 11, the mask pattern 310 is removed. The plurality of first apertures 320 extend in the first direction (x-axis direction) to expose the substrate 110. The plurality of first aperture 320 may include long first apertures 322 and short first apertures 324. The long first apertures 322 are disposed between and outside the short first apertures 324 in the third direction (z-axis direction). The long first apertures 322 may completely penetrate the first to third sacrificial layers 122, 140, and 124, the first to third insulating layers 132, 150, and 134, the base insulating layer 112a, and the cover insulating layer 160 to expose the substrate 110, and may partially penetrate the insulating pillar 112 to expose the substrate 110. In contrast, the short first apertures 324 may completely penetrate the cover insulating layer 160 and the third sacrificial layer 124 to expose the substrate 110, and may partially penetrate the first and second sacrificial layer 122 and 140, the first to third insulating layers 132, 150, and 134, and the base insulating layer 112a to expose the substrate.

Specifically, the long first apertures 322 may completely penetrate the first to third sacrificial layers 122, 140, and 124, and the first to third insulating layers 132, 150, and 134 to expose the substrate 110 in both portions which extend in the first direction (x-axis direction) and a portion which extends in the second direction (y-axis direction). However, the short first apertures 324 may completely penetrate the third sacrificial layer 124 to expose the substrate 110 in both a portion which extends in the first direction (x-axis direction) and a portion which extends in the second direction (y-axis direction) but may partially penetrate the first to second sacrificial layers 122 and 140 and the first and second insulating layers 132 and 150 to expose the substrate in portions which extend the first direction (x-axis direction).

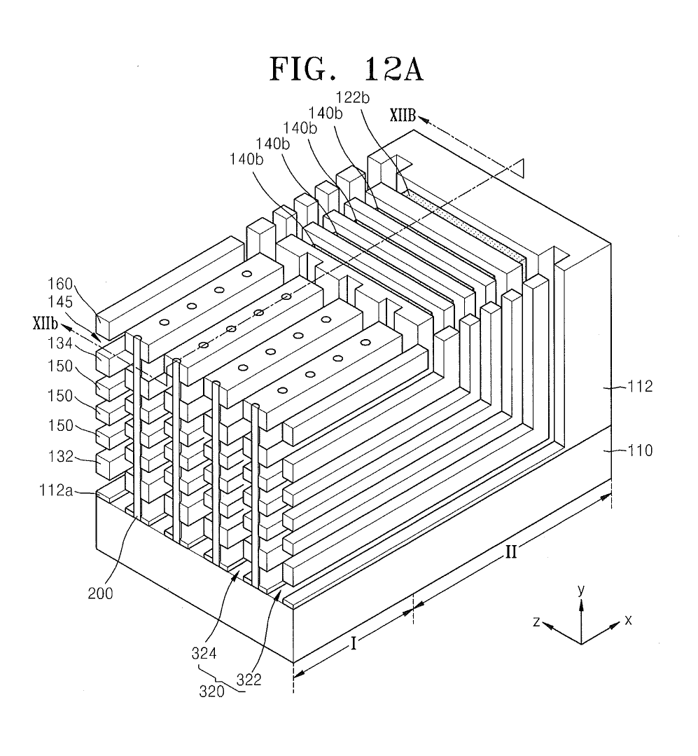

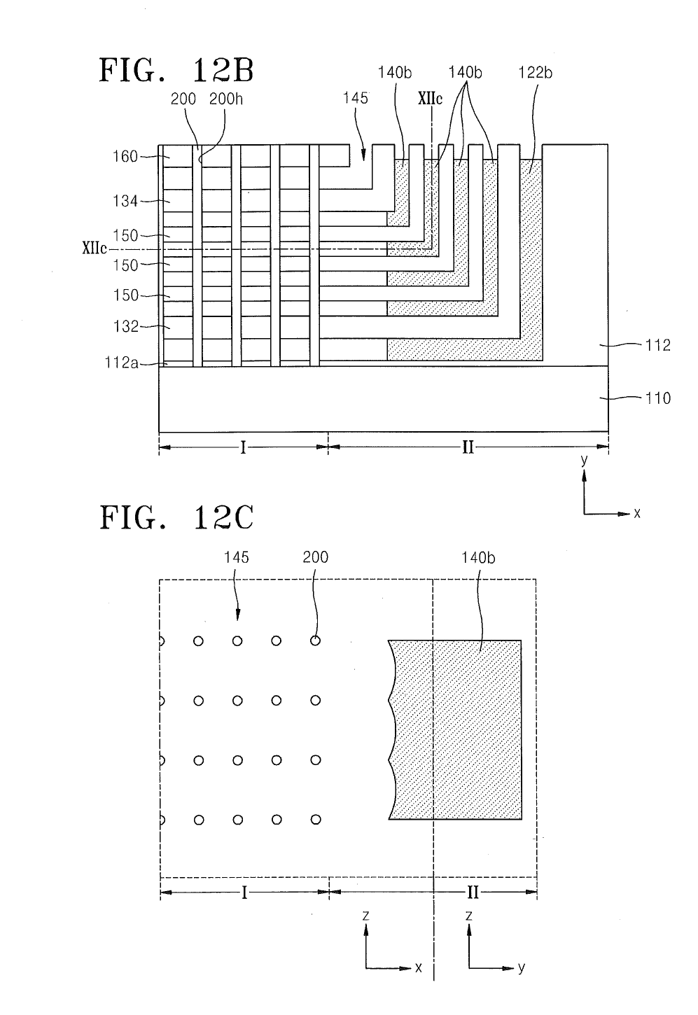

FIGS. 12A to 12C are perspective and cross-sectional views illustrating a process of forming first and second remnant sacrificial layers 122b and 140b according to an embodiment of the inventive concept. In detail, FIG. 12A is a perspective view illustrating the process of forming the first and second remnant sacrificial layers 120b and 140b.

Referring to FIGS. 11 and 12A, a portion of the first sacrificial layer 122, a portion of the second sacrificial layer 140 and most or all of the third sacrificial layer 124 are removed through the first apertures 320 and upper exposed surfaces of the first to third sacrificial layers 122, 140, and 124. For example, isotropic etching may be used to remove a portion of the first sacrificial layer 122, a portion of the second sacrificial layer 140 and all the third sacrificial layer 124. That is, an etchant may be applied onto the insides of the first apertures 320 and the upper exposed surfaces of the first to third sacrificial layers 122, 140, and 124 in the device region I. Here, isotropic etching may include wet etching or chemical dry etching (CDE). In this case, a time period during which the etchant is applied onto the first to third sacrificial layers 122, 140, and 124 may be controlled to obtain the first and second remnant sacrificial layers 120b and 140b that remain in the connection region II after the isotropic etching. That is, isotropic etching may be performed until the first to third sacrificial layers 122, 140, and 124 are removed completely only in the device region I while the first and second remnant sacrificial layers 122b and 140b remain and the third sacrificial layer 124 is completely removed in the connection region II. Hereinafter, the first remnant sacrificial layer 122b and the second remnant sacrificial layer 140b may also be referred to as a ‘lower supporting insulating layer’ and a ‘supporting insulating layer’, respectively. Spaces from which portions of the first and second sacrificial layers 122 and 140 and the third sacrificial layer 124 are removed may be referred to as ‘removal spaces 145’ for convenience of explanation.

The first to third sacrificial layers 122, 140, and 124 are relatively thin between at least two adjacent first apertures 320 not only in the device region I in which the plurality of first apertures 320 (i.e., the long first apertures 322 and the short first apertures 324) are arranged at predetermined intervals in the third direction (z-axis direction), but also in a portion of the connection region II adjacent to the device region I. However, the first and second sacrificial layers 122 and 140 are relatively thick between the long first apertures 322 in portions of the connection region II, in which only the long first apertures 322 are arranged in the third direction (z-axis direction) and that are spaced apart from the device region I. Accordingly, the first remnant sacrificial layer 122b and the second remnant sacrificial layer 140b may be formed based on this fact.

FIG. 12B is a cross-sectional view illustrating a process of forming first and second remnant sacrificial layers 122b and 140b according to an embodiment of the inventive concept. In detail, FIG. 12B is a cross-sectional view taken along the line XIIb-XIIb of FIG. 12A.

Referring to FIG. 12B, the first remnant sacrificial layer 122b and the second remnant sacrificial layers 140b remain between the insulating pillar 112/base insulating layer 112a and the first insulating layer 132, between the first insulating layer 132 and an adjacent second insulating layer 150, between adjacent second insulating layers 150, and between the third insulating layer 134 and an adjacent second insulating layer 150. If the first remnant sacrificial layer 122b and the second remnant sacrificial layers 140b do not remain, then the first to third insulating layers 132, 150, and 134 may need to be floated the connection region II, which may be difficult and/or impossible when the first to third insulating layers 132, 150, and 134 are relatively thin. Accordingly, the first remnant sacrificial layer 122b and the second remnant sacrificial layers 140b may support the first to third insulating layers 132, 150, and 134, and may thus also be referred to as the ‘lower supporting insulating layer’ and the ‘supporting insulating layers’, respectively, as described above.

The lower supporting insulating layer 122b and the supporting insulating layers 140b are formed by partially removing the exposed portions of the first sacrificial layer 122 and the second sacrificial layers 140 of FIG. 11. Thus, sides of the lower supporting insulating layer 122b and the supporting insulating layers 140b in the second direction (y-axis direction) may be arranged in the first direction (x-axis direction). Also, sides of the lower supporting insulating layer 122b and the supporting insulating layers 140b adjacent the device region I may be arranged in the second direction (y-axis direction).

In contrast, the first to third insulating layers 132, 150, and 134 may be supported by the semiconductor pole 200 without additional supporting layers in the device region I and a portion of the connection region II adjacent to the device region I.

FIG. 12C is another cross-sectional view illustrating the method of FIG. 12B. In detail, FIG. 12C is a cross-sectional view taken along the line XIIc-XIIc of FIG. 12B, which follows a path of the second remnant sacrificial layer 140b.

Referring to FIG. 12C, the supporting insulating layer 140b may be an L-shaped structure that is a combination of a plane extending in the first direction (x-axis direction) and a plane extending in the second direction (y-axis direction) and that extends in the third direction (z-axis direction). However, a side of the supporting insulating layer 140b adjacent to the device region I may be bent slightly due to the exposed surfaces of the second sacrificial layer 140 through the short first apertures 324 as shown in FIG. 11.

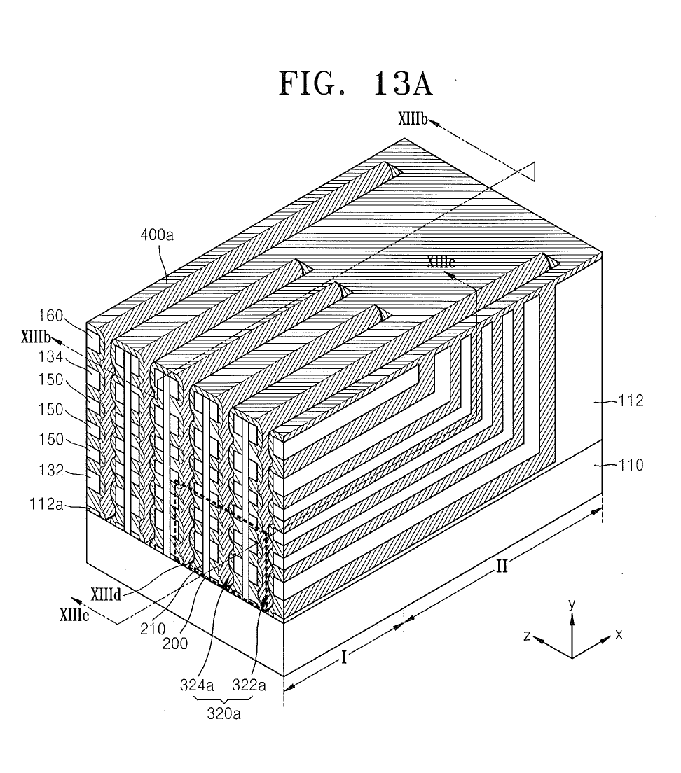

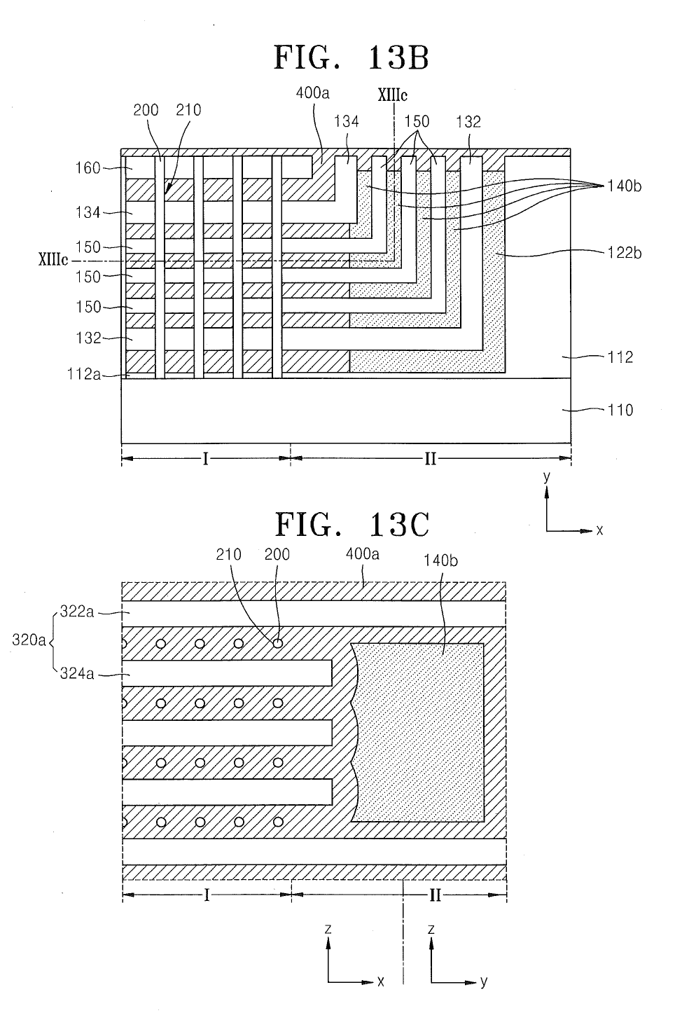

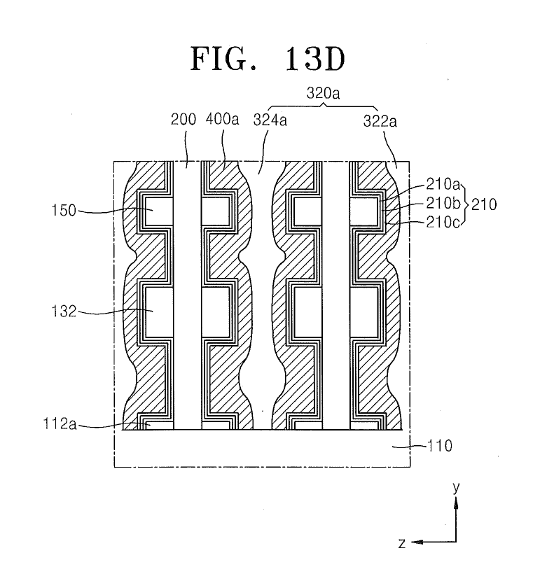

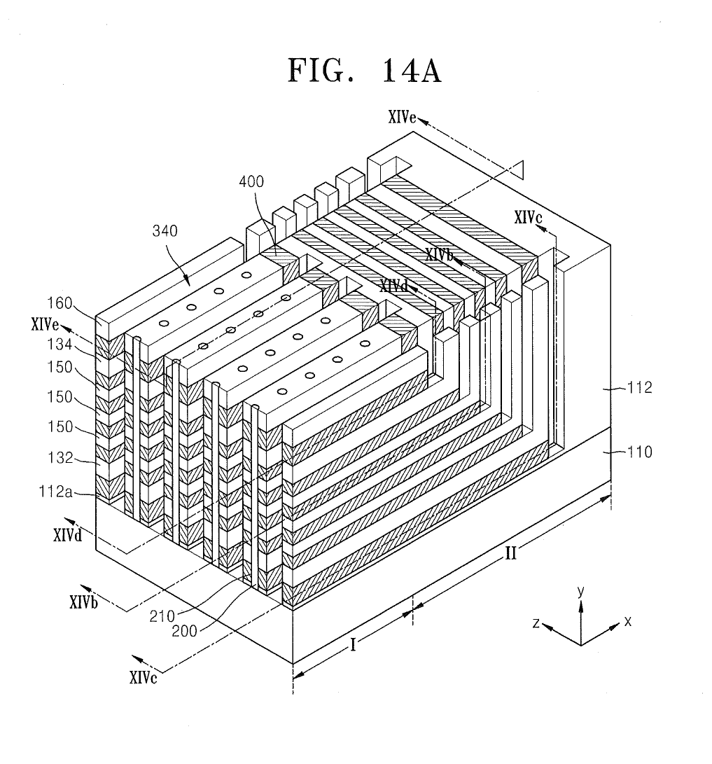

FIGS. 13A to 13D are perspective and cross-sectional views illustrating a process of forming a gate insulating layer 210 and a preliminary conductive layer 400a according to an embodiment of the inventive concept. FIG. 13A is a perspective view illustrating the process of forming the gate insulating layer 210 and the preliminary conductive layer 400a.

Referring to FIGS. 11, 12A, and 13A, the gate insulating layer 210 and the preliminary conductive layer 400a that covers the gate insulating layer 210 are formed on a surface exposed via the first aperture 320 and the removal spaces 145, and particularly, a surface of the semiconductor pole 200. The structure of the gate insulating layer 210 will be described later in detail.

The preliminary conductive layer 400a may be formed of, for example, doped polysilicon or metal. The preliminary conductive layer 400a may be formed by chemical vapor deposition (CVD). The preliminary conductive layer 400a may be formed in such a manner that the first aperture 320 is not completely filled with the preliminary conductive layer 400a so as to form a first groove 320a. That is, a first long groove 322a and a first short groove 324a, the widths of which are less than those of the long first aperture 322 and the short first aperture 324, respectively, may be obtained by partially filling the long first aperture 322 and the short first aperture 324 that constitute the first aperture 320 with the preliminary conductive layer 400a.

If the width of the first aperture 320, i.e., the length of the first aperture 320 in the third direction (z-axis direction), is greater than the thicknesses of the first to third sacrificial layers 122, 140, and 124, then the first groove 320a may be formed by completely filling the removal spaces 145 with the preliminary conductive layer 400a and partially filling the first aperture 320 with the preliminary conductive layer 400a.

Unlike as shown in the drawings, the preliminary conductive layer 400a may be partially bent or may have irregular parts. For example, a surface of the preliminary conductive layer 400a formed in the connection region II may be bent partially or may have irregular parts, caused by the lower supporting insulating layer 122b and the supporting insulating layers 140b.

FIG. 13B is a cross-sectional view illustrating the process of FIG. 13A, in which the gate insulating layer 210 and the preliminary conductive layer 410a are formed. In detail, FIG. 13B is a cross-sectional view taken along the line XIIIb-XIIIb of FIG. 13A.

Referring to FIGS. 12B and 13B, gaps between the cover insulating layer 160 and the third insulating layer 134, between the third insulating layer 134 and an adjacent second insulating layer 150, between adjacent second insulating layers 150, between the first insulating layer 132 and an adjacent second insulating layer 150, and between the first insulating layer 132 and the insulating pillar 112/base insulating layer 112a may be filled completely with the preliminary conductive layer 400a. Before the preliminary conductive layer 400a is formed, the gate insulating layer 210 may be formed on exposed surfaces of the semiconductor poles 200, the first to third insulating layers 132, 150, and 134 and the insulating pillar 112/base insulating layer 112a. Thus, the preliminary conductive layer 400a may cover surfaces of the semiconductor poles 200, having the gate insulating layer 210 therebetween.

FIG. 13C is another cross-sectional view illustrating the process of FIG. 13A, in which the gate insulating layer 210 and the preliminary conductive layer 400a are formed. In detail, FIG. 13C is a cross-sectional view taken along the line XIIIc-XIIIc of FIGS. 13A and 13B.

Referring to FIGS. 12C and 13C, spaces between the second insulating layers 150 except for the supporting insulating layers 140b and the semiconductor poles 200 are filled with the preliminary conductive layer 400a. In this case, the gate insulating layer 210 may be formed between the preliminary conductive layers 400a and the semiconductor poles 200. Thus, portions of the semiconductor poles 200, which contact the preliminary conductive layers 400a, may act as channel regions of the plurality of memory cells MC1 to MCn, the string selection transistors SST, and the ground selection transistors GST of FIG. 1.

Although a portion of the gate insulating layer 210 may be formed around the supporting insulating layers 140b, the features and functions of the non-volatile memory device 100 may not be significantly influenced by the gate insulating layer 210, and thus, the portion of the gate insulating layer 210 which formed around the supporting layers 140b may be regarded as being a portion of each of the supporting insulating layers 140b.

FIG. 13D is another cross-sectional view illustrating the process of FIG. 13A, in which the gate insulating layer 210 and the preliminary conductive layer 410a are formed. In detail, FIG. 13D is an enlarged cross-sectional view taken along the line XIIId-XIIId of FIG. 13A.

Referring to FIG. 13D, the gate insulating layer 210 is formed between the semiconductor pole 200 and the preliminary conductive layer 400a. The gate insulating layer 210 may be foamed by sequentially stacking a tunneling insulating layer 210a, a charge storing layer 210b, and a blocking insulating layer 210c on a side surface of the semiconductor pole 200. Although not shown in detail in the subsequent drawings, the gate insulating layer 210 may have a structure as illustrated in FIG. 13D unless described otherwise.

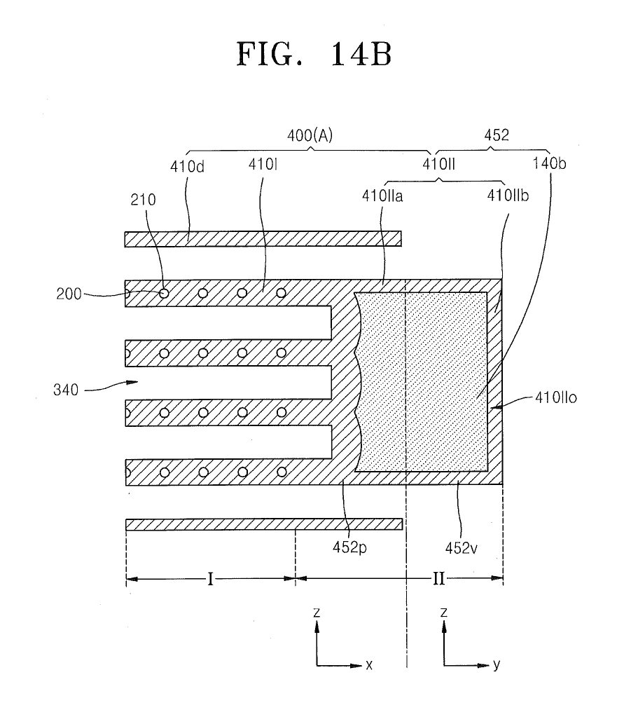

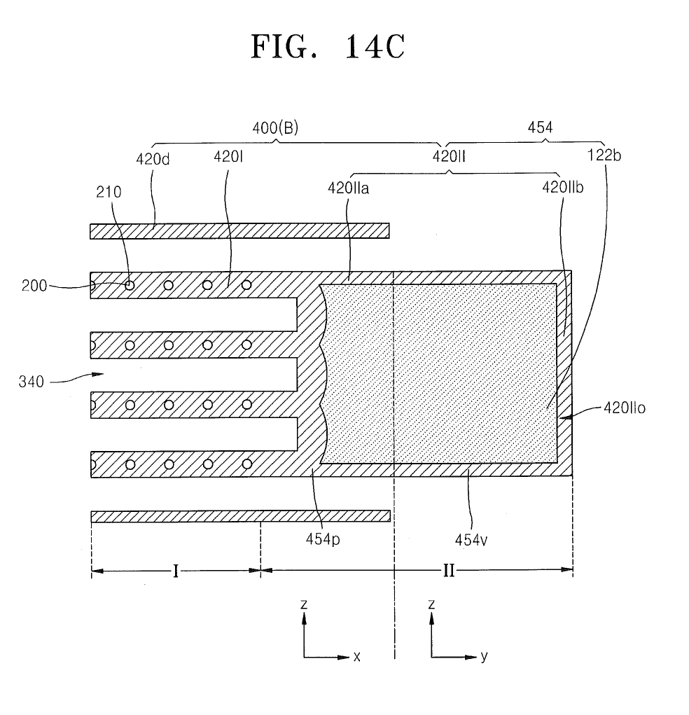

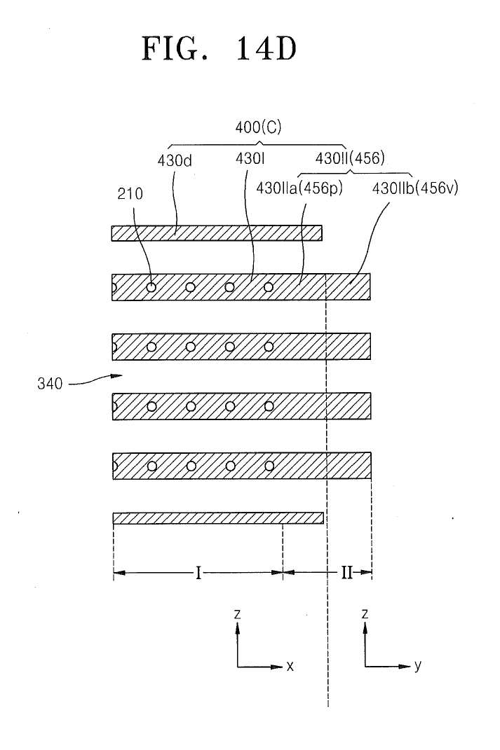

FIGS. 14A to 14E are perspective and cross-sectional views illustrating a process of forming a conductive layer 400 according to an embodiment of the inventive concept. FIG. 14A is a perspective view illustrating the process of forming the conductive layer 400.

Referring to FIGS. 13A and 14A, the conductive layer 400 may be formed by isotropic-etching the preliminary conductive layer 400a. A plurality of second apertures 340 are formed in spaces from which the preliminary conductive layer 400a is removed. Specifically, all portions of the preliminary conductive layer 400a, which are formed on side surfaces of the first to third insulating layers 132, 150, and 134, the insulating pillar 112, the base insulating layer 112a, and the cover insulating layer 160, may be removed.

That is, in the device region I, a portion of the preliminary conductive layer 400a, which is formed in each of the first apertures 320, is removed and the conductive layer 400 may thus extend in the first direction (x-axis direction). The conductive layers 400 extending in the first direction (x-axis direction) in the device region I may correspond to the word lines WL1 to WLn, the string selection lines SSL1 and SSL2, and the ground selection lines GSL1 and GSL2 of FIG. 1.

Similar to the preliminary conductive layers 400a, the conductive layers 400 may be bent partially or may have irregular parts unlike as shown in the drawings.

FIG. 14B is a cross-sectional view illustrating the process of FIG. 14A, in which the conductive layers 400 are formed. In detail, FIG. 14B is a cross-sectional view taking along the line XIVb-XIVb of FIG. 14A. Referring to FIGS. 14A and 14B, each of first conductive layers 400(A) includes a gate line 410I formed in the device region I and a gate connection unit 410II formed in the connection region II. Here, the first conductive layers 400(A) denote portions obtained by dividing the conductive layer 400 between the first insulating layer 132 and the third insulating layer 134 by the second insulating layers 150.

The gate line 410I may extend in the first direction (x-axis direction) while covering surfaces of the semiconductor poles 200 having the gate insulating layer 210 between the gate line 410I and the semiconductor poles 200, and may correspond to the word lines WL1 to WLn connected to the gates of the memory cells MC1 to MCn of FIG. 1. A plurality of gate lines 410I may be disposed apart from one another by the second apertures 340.

The gate connection unit 410II is a portion of the first conductive layer 400(A), which is formed in the connection region II, and is connected to the plurality of gate lines 410I at the same level from the substrate 110. The plurality of gate lines 410I and the gate connection unit 410II may have the same thickness since all of them are formed in the spaces from which the second sacrificial layers 140 of FIG. 6A have been removed. The gate connection unit 410II includes a horizontal part 410IIa that extends in the first direction (x-axis direction), and a pillar part 410IIb that is combined with the horizontal part 410IIa in a single body and extends in the second direction (y-axis direction). In the gate connection unit 410II, an aperture or cavity 410IIo may be formed in a space defined by the horizontal part 410IIa and the pillar part 410IIb. The aperture 410IIo may be filled with the supporting insulating layer 140b.

The gate connection unit 410II may surround the supporting insulating layer 140b. Thus, two portions of the pillar part 410IIb extending in the second direction (y-axis direction) are disposed outside a region where the supporting insulating layer 140b are disposed, respectively. The two portions of the pillar part 410IIb extending in the second direction (y-axis direction) are connected by a portion of the pillar part 410IIb formed on the supporting insulating layer 140b in the second direction (y-axis direction).

One end of the horizontal part 410IIa may be connected to the plurality of gate lines 410I and the other end thereof may be connected to the pillar part 410IIb. That is, the horizontal part 410IIa may be disposed between the plurality of gate lines 410I connected to the horizontal part 410IIa and the pillar part 410IIb.

The gate connection unit 410II is formed in all the spaces from which the second sacrificial layers 140 of FIG. 6A have been removed, except for the second apertures 340. Thus, if the plurality of second sacrificial layers 140 are formed, a plurality of gate connection units 410II are formed. The plurality of gate connection units 410II may be referred to as a ‘gate connection unit group’ or a ‘gate connection structure’. The plurality of gate connection units 410II may be connected to the gate lines 410I at the same level from the substrate 110, respectively.

The supporting insulating layers 140b may be disposed in spaces corresponding to the apertures or cavities 410IIo so as to retain spaces for forming the gate connection units 410II.

In the connection region II, the gate connection unit 410II and the supporting insulating layer 140b form an L-shaped structure 452 extending in the third direction (z-axis direction). Spaces between the first insulating layer 132 and an adjacent second insulating layer 150, between adjacent second insulating layers 150, and between the third insulating layer 134 and an adjacent second insulating layer 150 may be filled with the L-shaped structure 452. The L-shaped structure 452 may include a horizontal part 452p extending in the first direction (x-axis direction) and a vertical part 452v extending in the second direction (y-axis direction).

The first conductive layer 400(A) may further include a first dummy conductive layer 410d disposed apart from the gate line 410I and the gate connection unit 410II but the first dummy conductive layer 410d may not be formed according to a manufacturing method and design.

FIG. 14C is another cross-sectional view illustrating the process of FIG. 14A, in which the conductive layers 400 are formed. In detail, FIG. 14C is a cross-sectional view along the line XIVc-XIVc of FIG. 14A.

Referring to FIGS. 14A and 14C, a second conductive layer 400(B) includes a lower gate line 420I formed in the device region I, and a lower gate connection unit 420II formed in the connection region II. The second conductive layer 400(B) corresponds to portions of the conductive layer 400 between the base insulating layer 112a/the insulating pillar 112 and the first insulating layer 132.

The lower gate line 420I may cover surfaces of the semiconductor poles 200 having the gate insulating layer 210 between the lower gate line 420I and the semiconductor poles 200, may extend in the first direction (x-axis direction), and may correspond to the ground selection lines GSL1 and GSL2 connected to the gates of the ground selection transistors GST of FIG. 1. A plurality of lower gate lines 420I may be disposed apart from each other by the second apertures 340.

The lower gate connection unit 420II is a portion of the second conductive layer 400(B) in the connection region II and is connected to the plurality of lower gate lines 420I. The lower gate connection unit 420II includes a lower horizontal part 420IIa that extends in the first direction (x-axis direction), and a lower pillar part 420IIb that is combined with the horizontal part 420IIa in a single body and extends in the second direction (y-axis direction). In the gate connection unit 420II, a lower aperture 420IIo may be formed in a space defined by the lower horizontal part 420IIa and the lower pillar part 420IIb. The lower aperture 420IIo may be filled with the lower supporting insulating layer 122b.

The lower supporting insulating layer 122b may be disposed in a space corresponding to the lower aperture 420IIo so as to retain a space for forming the lower gate connection unit 420II.

As described above with reference to FIG. 12B, sides of the lower supporting insulating layer 122b and the supporting insulating layers 140b in the second direction (y-axis direction) may be arranged in the first direction (x-axis direction). Thus, sides of the lower aperture 420IIo and the plurality of apertures 410IIo, in which the lower supporting insulating layer 122b and the supporting insulating layers 140b, in the second direction (y-axis direction), are disposed may be arranged in the first direction (x-axis direction). Likewise, sides of the lower aperture 420IIo and the plurality of apertures 410IIo adjacent to the device region I may be arranged in the second direction (y-axis direction).

The lower gate connection unit 420II and the lower supporting insulating layer 1220b may form an L-shaped lower structure 454 extending in the third direction (z-axis direction) in the connection region II. Spaces between the base insulating layer 112a/the insulating pillar 112 and the first insulating layer 132 may be filled with the L-shaped lower structure 454. The L-shaped lower structure 454 may include a lower horizontal part 454p extending in the first direction (x-axis direction) and a lower vertical part 454v extending in the second direction (y-axis direction).

The second conductive layer 400(B) may further include a second dummy conductive layer 420d disposed apart from the lower gate line 420I and the lower gate connection unit 420II. However the second dummy conductive layer 420d may not be formed according to a manufacturing method and design.

FIG. 14D is another cross-sectional view illustrating the process of FIG. 14A, in which the conductive layers 400 are formed. In detail, FIG. 14D is a cross-sectional view taken along the line XIVd-XIVd of FIG. 14A.

Referring to FIGS. 14A and 14D, a third conductive layer 400(C) includes an upper gate line 430I formed in the device region I, and an upper gate connection unit 430II formed in the connection region II. The third conductive layer 400(C) corresponds to portions of the conductive layer 400 between the second insulating layer 150 and the cover insulating layer 160.

The upper gate line 430I may extend in the first direction (x-axis direction) while covering surfaces of the semiconductor poles 200 having the gate insulating layer 210 between the upper gate line 430I and the semiconductor poles 200, and may correspond to the string selection lines SS1 and SS2 connected to the gates of the string selection transistors SST of FIG. 1. A plurality of upper gate lines 430I and a plurality of upper gate connection units 430II may be disposed apart from one another by the second apertures 340. The plurality of upper gate connection units 430II may be connected to the plurality of upper gate lines 430I, respectively.

Compared to the gate connection unit 410II and the lower gate connection unit 420II, the upper gate connection unit 430II may also be regarded as an upper L-shaped structure 456 extending in the third direction (z-axis direction) in the connection region II. However, compared to the gate connection unit 410II and the lower gate connection unit 420II, the plurality of upper L-shaped structures 456 are disposed apart from one another by the second apertures 340. In other words, the L-shaped structures 456 of the upper gate connection unit 430II are not electrically connected to one another.

A space between the third insulating layer 134 and the cover insulating layer 160 may be filled with the upper L-shaped structure 456. The upper L-shaped structure 456 may include an upper horizontal part 456p extending in the first direction (x-axis direction) and an upper vertical part 456v extending in the second direction (y-axis direction). Compared to the gate connection unit 410II and the lower gate connection unit 420II, the upper horizontal part 456p and the upper vertical part 456v may be regarded as an upper horizontal part 430IIa and an upper pillar part 430IIb, respectively.

Since the upper gate connection unit 430II, that is, the upper L-shaped structure 456 may not need a supporting structure to be included therein, the upper horizontal part 456p and the upper pillar part 456v of the upper L-shaped structure 456 may extend continuously in the first direction (x-axis direction) and the second direction (y-axis direction).

The third conductive layer 400(C) may further include a third dummy conductive layer 430d disposed apart from the upper gate line 430I and the upper gate connection unit 430II but the third dummy conductive layer 430d may not be formed according to a manufacturing method and design.

FIG. 14E is another cross-sectional view illustrating the process of FIG. 14A, in which the conductive layers 400 are formed. In detail, FIG. 14E is a cross-sectional view taken along the line XIVe-XIVe of FIG. 14A.

Referring to FIGS. 14A to 14E, the supporting insulating layer 140b may have upper and lower surfaces at the same level as the gate connection unit 410II. Likewise, the lower supporting insulating layer 122b may have upper and lower surfaces at the same level as the lower gate connection unit 420II. As described above with reference to FIG. 5, if the first and second preliminary sacrificial layers 122a and 140a are formed of the same material, then the supporting insulating layer 140b and the lower supporting insulating layer 122b that are remnant portions of the first and second preliminary sacrificial layers 122a and 140a, respectively, may also be formed of the same material.

The gate connection unit 410II may be connected to the gate lines 410I at the same level from the substrate 110, and the horizontal part 410IIa of the gate connection unit 410II may have upper and lower surfaces at the same level as the gate lines 410I. Likewise, the lower gate connection unit 420II may be connected to the lower gate lines 420I, and the lower horizontal part 420IIa of the lower gate connection unit 420II may have upper and lower surfaces at the same level as the lower gate lines 420I. Also, the upper gate connection unit 430II may be connected to the lower gate lines 430I, and the upper horizontal part 430IIa of the upper gate connection unit 430II may have upper and lower surfaces at the same level as the upper gate lines 430I.

The second insulating layers 150 may be divided into a portion 150I formed in the device region I and a portion 150II formed in the connection region II. The portion 150II of the second insulating layer 150 formed in the connection region II may be referred to as a ‘first interlevel insulating layer 150II’. Also, the portion 150I of the second insulating layer 150 formed in the device region I may be referred to as a ‘fourth interlevel insulating layers 150I’. The first interlevel insulating layer 150II is disposed between the L-shaped structures 452 and is thus disposed between the gate connection units 410II. The first interlevel insulating layer 150II may be formed of a material having a different etch selectivity from that of the supporting insulating layer 140b included in the L-shaped structure 452, since the first interlevel insulating layer 150II and the supporting insulating layer 140b are remnant portions of the second preliminary insulating layer 150a and the second preliminary sacrificial layer 140a of FIG. 5, respectively. The first interlevel insulating layer 150II may be divided into a portion 150IIp extending in the first direction (x-axis direction) and a portion 150IIv extending in the second direction (y-axis direction). The portion 150IIv of the first interlevel insulating layer 150II that extends in the second direction (y-axis direction), i.e., the first interlevel insulating layer 150II between adjacent pillar parts 410IIb, has a first thickness t1. That is, the first thickness t1 indicates the distance between the pillar part 410IIb and the first interlevel insulating layer 150II in the first direction (x-axis direction).

The third insulating layer 134 may be divided into a portion 134I formed in the device region I and a portion 134II formed in the connection region II. The portion 134II formed in the connection region II may be referred to as a ‘second interlevel insulating layer 134II’. The second interlevel insulating layer 134II is disposed between the upper gate connection unit 430II and an adjacent gate connection unit 410II. Thus, the second interlevel insulating layer 134II is disposed between the upper gate connection unit 430II and the gate connection unit group. The second interlevel insulating layer 134II may be divided into a portion 134IIp extending in the first direction (x-axis direction) and a portion 134IIv extending in the second direction (y-axis direction). The portion 134IIv of the second interlevel insulating layer 134II extending in the second direction (y-axis direction) has a second thickness t2. The second thickness t2 indicates the distance between the upper pillar portion 456v and the second interlevel insulating layer 134II in the first direction (x-axis direction).

The first insulating layer 132 may be divided into a portion 132I formed in the device region I and a portion 132II formed in the connection region II. The portion 132II of the first insulating layer 132 formed in the connection region II may be referred to as a ‘third interlevel insulating layer 132II’. The third interlevel insulating layer 132II is disposed between the lower gate connection unit 420II and an adjacent gate connection unit 410II. Thus, the third interlevel insulating layer 132II is disposed between the lower gate connection unit 420II and the gate connection unit group. Also, the third interlevel insulating layer 132II is divided into a portion 132IIp extending in the first direction (x-axis direction) and a portion 132IIv extending in the second direction (y-axis direction). The portion 132IIv of the third interlevel insulating layer 132II that extends in the second direction (y-axis direction) has a third thickness t3. That is, the third thickness t3 indicates the distance between the lower pillar part 420IIb and the third interlevel insulating layer 132II in a direction opposite to the first direction (x-axis direction).

If the thickness of the third insulating layer 134 is greater than that of the first insulating layer 132 as illustrated in FIG. 6, the second thickness t2 may be greater than the first thickness t1. If the thickness of the third insulating layer 134 is greater than that of the second insulating layer 150 as illustrated in FIG. 6, the third thickness t3 may be less than the second thickness t2. That is, when only some portions of the third insulating layer 134 are to be exposed via the short linear spaces 314 of the mask pattern 310 as illustrated in FIG. 10, the third insulating layer 134 may need to be relatively thick, considering processing margins for forming the mask pattern 310.

The fourth interlevel insulating layer 150I that is a portion of the second insulating layer 150 disposed between adjacent gate lines 410I in the second direction (y-axis direction), that is, the fourth interlevel insulating layer 150I disposed between gate lines 410I that constitute memory cells of a selected NAND cell string, constitutes a portion of the second insulating layer 150, together with the first interlevel insulating layer 150II. Thus, the first interlevel insulating layer 150II and the fourth interlevel insulating layer 150I may be formed of the same material.

The shorter the distances between the horizontal parts 410IIa of the gate connection units 410II and the substrate 110, the longer the gate connection units 410II in the first direction (x-axis direction). Similarly, the longer the horizontal parts 410IIa of the gate connection units 410II in the first direction (x-axis direction), the longer the pillar parts 410IIb of the gate connection units 410II in the second direction (y-axis direction).

FIG. 15 is a perspective view illustrating a process of forming contact plugs 600 according to an embodiment of the inventive concept. Referring to FIGS. 14A and 15, the second apertures 340 are filled with a burying insulating layer 500. The burying insulating layer 500 may be formed by applying an insulating material into the second apertures 340 so that the second apertures 340 are completely filled with the insulating material, and planarizing the insulating material, for example, by CMP until the conductive layer 400, and particularly, the pillar part 410IIb, the lower pillar part 420IIb, and the upper pillar part 430IIb are exposed.

The contact plugs 600 may be formed on the pillar parts 410IIb and the lower pillar part 420IIb so that the gate line 410II and the lower gate line 420II may be connected to an external circuit (not shown). Then, the non-volatile memory device 100 may be manufactured. As such, the contact plugs 600 may provide word line contact plugs. The contact plugs 600 may be arranged in a line between the first direction (x-axis direction) and the third direction (z-axis direction) and in a direction different from the first direction (x-axis direction) and the third direction (z-axis direction).

Also, although not shown, the burying insulating layer 500 may surround the contact plugs 600. In this case, the contact plugs 600 may be formed by forming contact holes (not shown) according to the photolithography process and filling the contact holes with a conductive material.

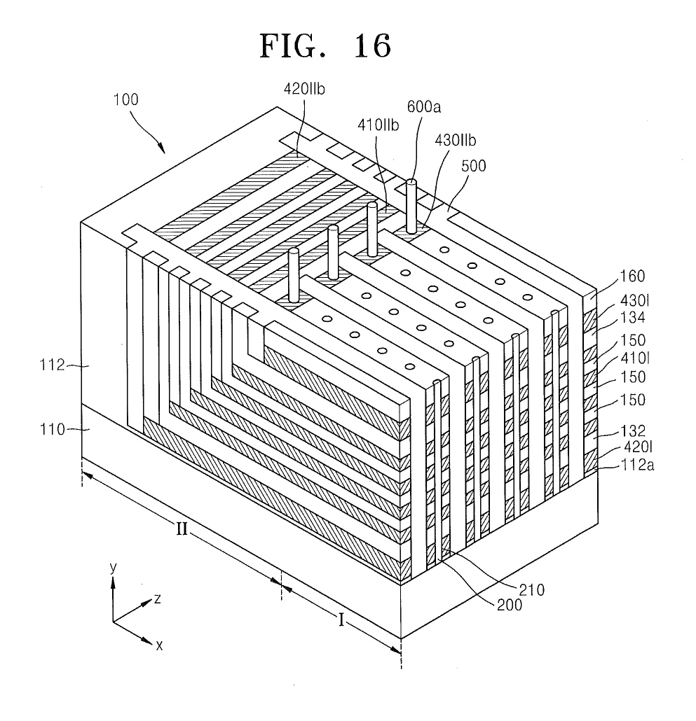

FIG. 16 is a perspective view illustrating a process of forming upper contact plugs 600a according to an embodiment of the inventive concept. In detail, FIG. 16 is a perspective view of a portion of the non-volatile memory device 100 of FIG. 15, extends in which extends in a direction opposite to the first direction (x-axis direction).

Referring to FIG. 16, the upper contact plugs 600a are formed on the upper pillar parts 430IIb that are electrically isolated and disposed apart from one another, via which the upper gate line 430II may be connected to an external circuit (not shown). As such, the contact plugs 600a may provide string select line contact plugs. The contact plugs 600a may be formed together with or separately from the contact plugs 600 of FIG. 15.

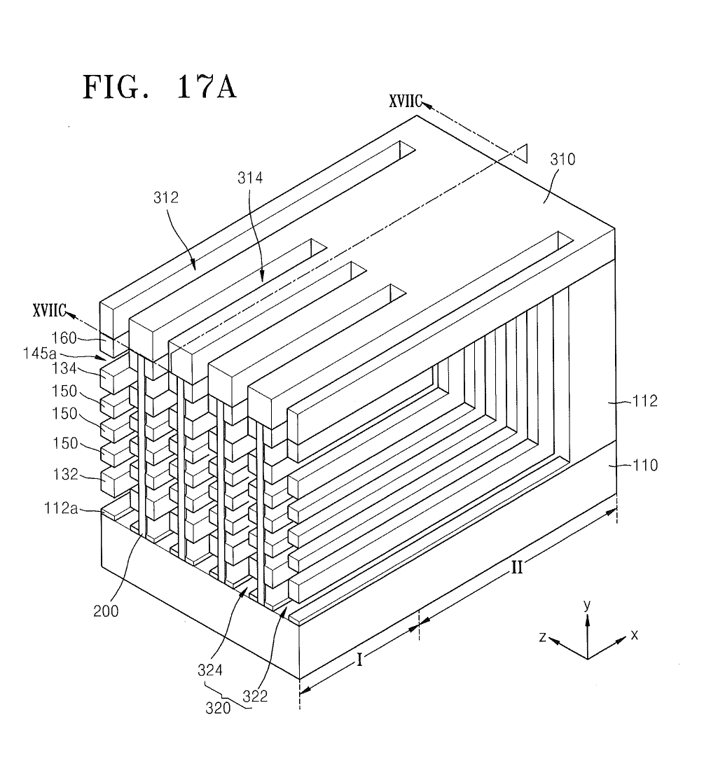

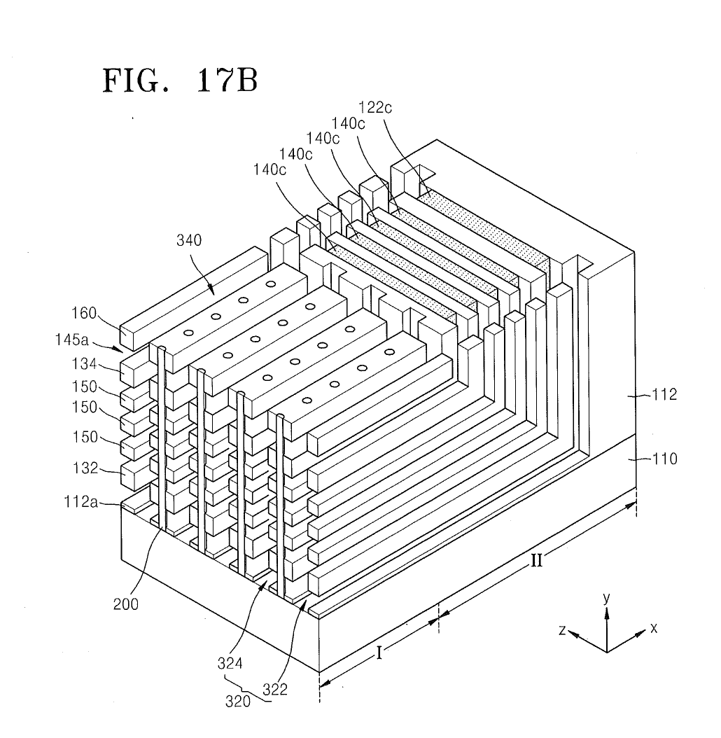

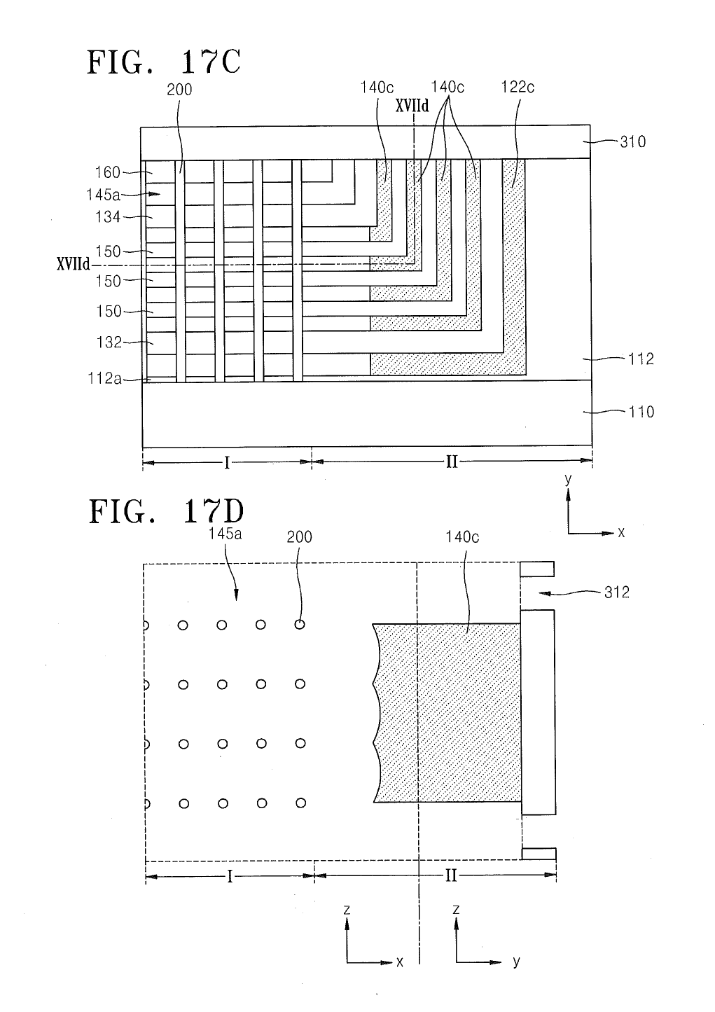

FIGS. 17A to 24 are views illustrating a structure of and method of fabricating a non-volatile memory device 102 according to another embodiment of the inventive concept. In detail, FIGS. 17A to 24 are views illustrating a structure of and method of fabricating the non-volatile memory device 102 after the processes of FIGS. 2 to 10 are performed. The components, structures, or processes described above with reference to FIGS. 11 to 16, which are the same as those of the current embodiment, will not be described again here.

FIGS. 17A to 17D are perspective and cross-sectional views illustrating a process of forming first and second remnant sacrificial layers 122c and 144c according to another embodiment of the inventive concept. FIG. 17A is a perspective view illustrating a process of forming the first and second remnant sacrificial layers 122c and 144c according to another embodiment of the inventive concept.

Referring to FIGS. 12A and 17A, a portion of the first sacrificial layer 122, a portion of the second sacrificial layer 140, and third sacrificial layers 124 are removed while a mask pattern 310 remains, unlike as shown in FIG. 12A. For example, isotropic etching may be performed to remove the first to third sacrificial layers 122, 140, 124. That is, an etchant may be applied onto the first to third sacrificial layers 122, 140, and 124 exposed via first apertures 320. Here, isotropic etching may include wet etching or CDE.

For convenience of explanation, spaces from which the first and second sacrificial layers 122 and 140 are removed partially and the third sacrificial layer 124 is removed, will be referred to as ‘removal spaces 145a’.

FIG. 17B is a perspective view illustrating the process of FIG. 17A, in which illustration of a mask pattern 310 is omitted for convenience of explanation.

Referring to FIGS. 17A and 17B, an etchant is not applied onto portions of the first and second sacrificial layers 122 and 140, which are covered with the mask pattern 310, in a connection region II, and thus, first and second remnant sacrificial layers 122c, and 144c that remain as remnant portions of the first and second sacrificial layers 122 and 140 in the connection region II may have upper surfaces at the same level with an insulating pillar 112 and first to third insulating layers 132, 150, and 134 with respect to a substrate 110.

FIG. 17C is a cross-sectional view illustrating the process of FIG. 17A. In detail, FIG. 17C is a cross-sectional view taken along the line XVIIc-XVIIc of FIG. 17A.

Referring to FIG. 17C, the first remnant sacrificial layer 122c and the second remnant sacrificial layer 140c remain between the insulting pillar 112/base insulating layer 112a and the first insulating layer 132, between the first insulating layer 132 and an adjacent second insulating layer 150, between adjacent second insulating layers 150, and between the third insulating layer 134 and an adjacent second insulating layer 150. If the first remnant sacrificial layer 122c and the second remnant sacrificial layer 140c do not remain, the first to third insulating layers 132, 150, and 134 may need to be floated in the connection region II, which may be difficult when the thicknesses thereof are relatively fine. Thus, the first remnant sacrificial layer 122c and the second remnant sacrificial layer 140c are used to support the first to third insulating layers 132, 150, and 134. The first remnant sacrificial layer 122c and the second remnant sacrificial layer 140c may also be referred to as a ‘lower supporting insulating layer’ and a ‘supporting insulating layer’, respectively, as describe above.

The lower supporting insulating layer 122c and the supporting insulating layer 140c are formed by partially removing exposed portions of the first sacrificial layer 122 and the second sacrificial layer 140 of FIG. 10. Thus, sides of the lower supporting insulating layer 122c and the supporting insulating layer 140c adjacent to a device region I may be arranged in the second direction (y-axis direction). Also, since sides of the lower supporting insulating layer 122c and the supporting insulating layer 140c in the second direction (y-axis direction) are covered with the mask pattern 320, the lower supporting insulating layer 122c and the supporting insulating layer 140c may be arranged in the first direction (x-axis direction) similar to the first sacrificial layer 122 and the second sacrificial layer 140. That is, the sides of the lower supporting insulating layer 122c and the supporting insulating layer 140c in the second direction (y-axis direction) may be disposed to be arranged with respect to the sides of the first to third insulating layers 132, 150, and 134 in the second direction (y-axis direction).

The first to third insulating layers 132, 150, and 134 may be supported by semiconductor poles 200 without any supporting layers in the device region I and a portion of the connection region II adjacent to the device region I.

FIG. 17D is another cross-sectional view illustrating the process of FIG. 17A. In detail, FIG. 17D is a cross-sectional view taken along the line XVIId-XVIId of FIG. 17C, which follows a path of the second remnant sacrificial layer 140c.

Referring to FIG. 17D, the supporting insulating layer 140c may be an L-shaped structure that is a combination of a plane extending in the first direction (x-axis direction) and a plane extending in the second direction (y-axis direction) and that extends in a third direction (z-axis direction). However, a side of the supporting insulating layer 140c adjacent to the device region I may be bent slightly due to the exposed surfaces of the second sacrificial layer 140 through the short linear spaces 314 as shown in FIG. 10.

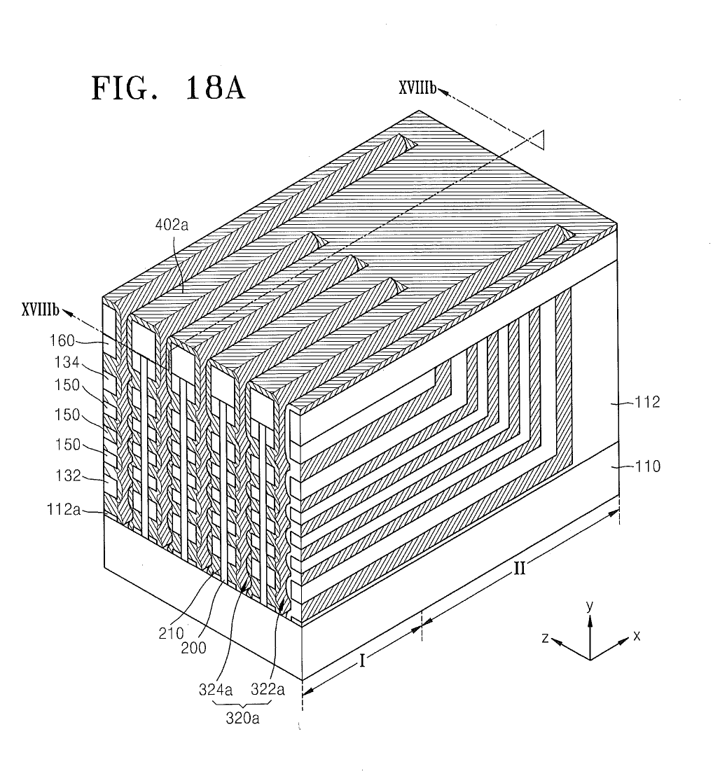

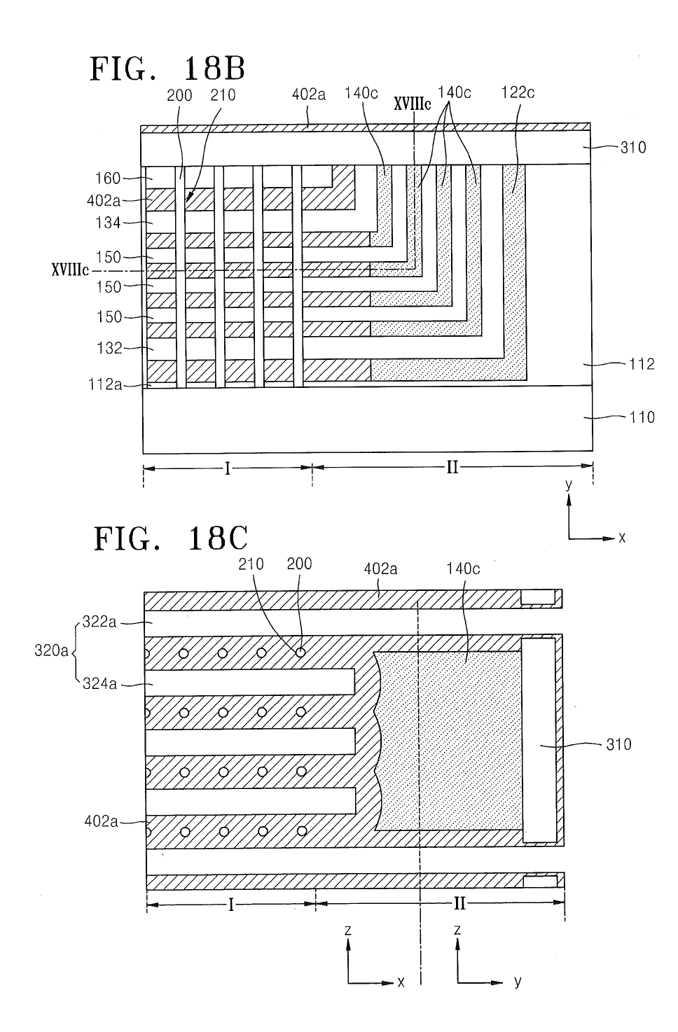

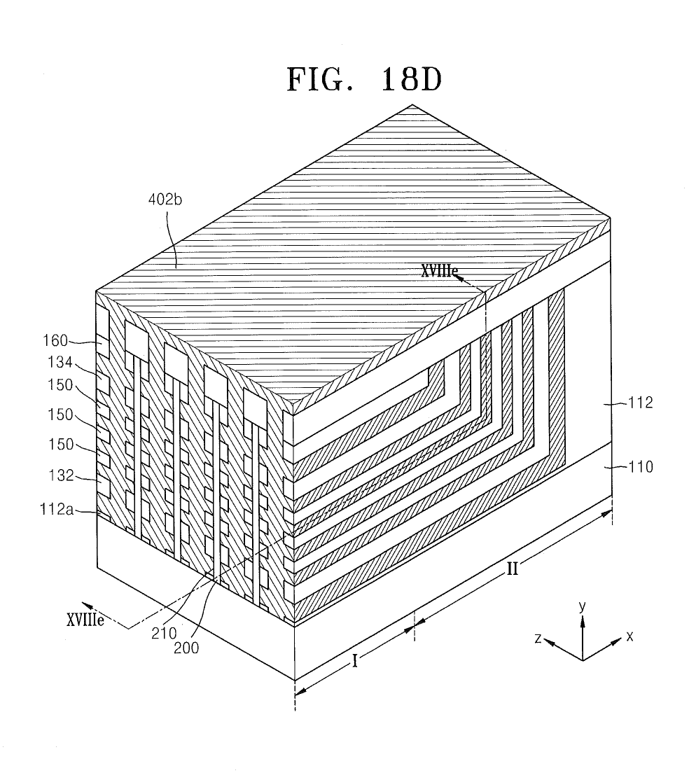

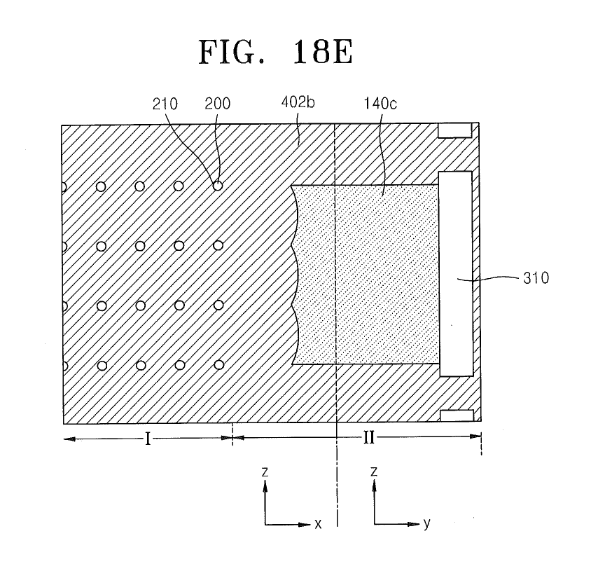

FIGS. 18A to 18E are perspective and cross-sectional views illustrating a process of forming a gate insulating layer 210 and a preliminary conductive layer 402a according to another embodiment of the inventive concept. FIG. 18A is a illustrating a process of forming the gate insulating layer 210 and the preliminary conductive layer 420a according to another embodiment of the inventive concept.

Referring to FIGS. 17A and 18A, the gate insulating layer 210 and the preliminary conductive layer 402a covering the gate insulating layer 210 are formed on surfaces of the resultant structure and particularly, the semiconductor poles 200, which are exposed via linear spaces 312 and 314, the first apertures 320, and the removal spaces 145a.

The preliminary conductive layer 402a may be formed of, for example, doped silicon or metal. The preliminary conductive layer 402a may be formed by CVD. The preliminary conductive layer 402a may be formed in such a manner that the first apertures 320 are not completely filled with the preliminary conductive layer 402a so as to form first grooves 320a. That is, a first long groove 322a and a first short groove 324a may be formed by partially filling a long first aperture 322 and a short first aperture 324, which constitute the first aperture 320, with the preliminary conductive layer 402a. The widths of the first long groove 322a and the first short groove 324a are less than those of the long first aperture 322 and the short first aperture 324.

If the width of the first aperture 320, i.e., the length thereof in the third direction (z-axis direction), is greater than the thicknesses of first to third sacrificial layers 122, 140, and 124, then the preliminary conductive layer 402a may be formed in such a manner that the removal spaces 145a are completely filled with the preliminary conductive layer 402a but the first apertures 320 is not completely filled with the preliminary conductive layer 402a, thereby forming the first grooves 320a.

Referring to FIG. 18A, the preliminary conductive layer 402a is formed while the mask pattern 310 remains, in contrast to FIG. 13A. Thus, the preliminary conductive layer 402a may be formed on an exposed surface of the mask pattern 310.

FIG. 18B is a cross-sectional view illustrating the process of FIG. 18A. In detail, FIG. 18B is a cross-sectional view taken along the line XVIIIb-XVIIIb of FIG. 18A.

Referring to FIGS. 17C, 18A, and 18B, the removal spaces 145a are completely filled with the gate insulating layer 210 and the preliminary conductive layer 402a. Thus, surfaces of the semiconductor poles 200 are covered with the preliminary conductive layer 420a, having the gate insulating layer 210 therebetween.

FIG. 18C is another cross-sectional view illustrating the process of FIG. 18A. In detail, FIG. 18C is a cross-sectional view taken along the line XVIIIc-XVIIIc of FIG. 18B.

Referring to FIG. 18C, the preliminary conductive layer 402a covers surfaces of the semiconductor poles 200 having the gate insulating layer 210 between the preliminary conductive layer 420a and the semiconductor poles 200. The portions of preliminary conductive layer 420 that cover the surfaces of the semiconductor poles 200 on the same plane (xy plane) are coupled to one another.

FIG. 18D is a perspective view illustrating a process of forming the gate insulating layer 210 and the preliminary conductive layer 402b according to another embodiment of the inventive concept. Referring to FIGS. 17A, 18A, and 18D, all the first aperture 320, the linear spaces 312 and 314, and the removal spaces 145a may be filled with the preliminary conductive layer 402b. In this case, the preliminary conductive layer 402b may also be formed to entirely cover the mask pattern 310.

FIG. 18E is a cross-sectional view illustrating the process of FIG. 18D. In detail, FIG. 18E is a cross-sectional view taken along the line XVIIIe-XVIIIe of FIG. 18E.

Referring to FIG. 18E, the preliminary conductive layer 402b may be formed in such a manner that all spaces are filled therewith on the same plane (xy plane). That is, all the first apertures 320, the linear spaces 312 and 314, and the removal spaces 145a may be filled with the preliminary conductive layer 402b.

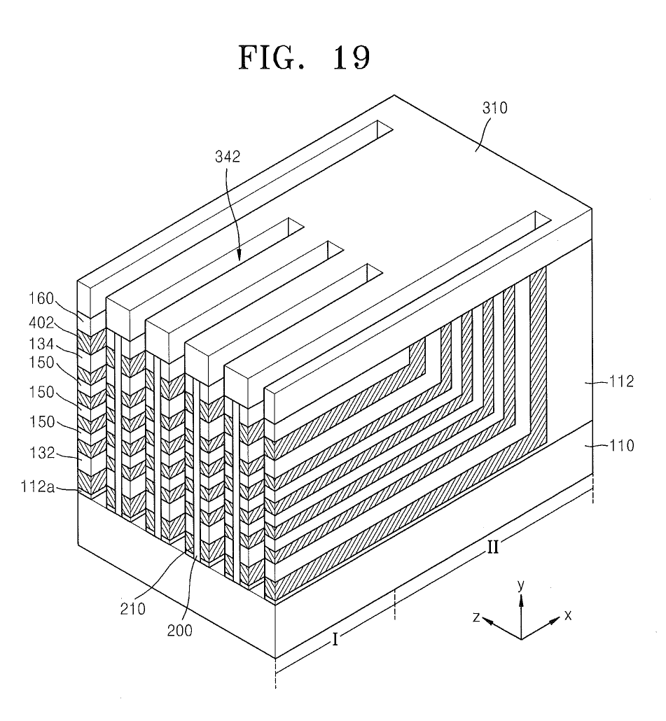

FIG. 19 is a perspective view illustrating a process of forming conductive layers 402 according to another embodiment of the inventive concept. Referring to FIGS. 18A and 19, the conductive layers 402 may be formed by isotropic or anisotropic etching the preliminary conductive layer 402a by using the mask pattern 310 as an etch mask. A plurality of second apertures 342 are formed in spaces from which the preliminary conductive layer 402a is removed. Thus, the preliminary conductive layer 402a may be removed from upper and side surfaces of the mask pattern 310, and side surfaces of the first to third insulating layers 132, 150, 134, the cover insulating layer 160, the preliminary insulating layer 112a, and the insulating pillar 112. In the device region I, the preliminary conductive layer 402a may be removed from the first apertures 320 of FIG. 10, and thus, the conductive layers 402 extend in the first direction (x-axis direction). The conductive layers 402 extending in the first direction (x-axis direction) in the device region I may correspond to the word lines WL1 to WLn, the string selection lines SSL1 and SSL2, and the ground selection lines GSL1 and GSL2 of FIG. 1.

Referring to FIGS. 18D and 19, the conductive layers 402 may be formed by anisotropic-etching the preliminary conductive layer 402b by using the mask pattern 310 as an etch mask.

The shape of the conductive layers 402 may be the same regardless of whether they are formed from the preliminary conductive layer 402a of FIG. 18A or from the preliminary conductive layer 402b of FIG. 18D but the type of etching process that can be used when the preliminary conductive layer 402a of FIG. 18A is used may be different from when the preliminary conductive layer 402b of FIG. 18D is used.

The conductive layer 400 illustrated in FIGS. 14A to 14E may be formed on the supporting insulating layer 140b in the second direction (y-axis direction) but the conductive layer 402 of FIG. 19 is prevented from being formed on the supporting insulating layer 140c in the second direction (y-axis direction) due to the mask pattern 310.

FIG. 20 is a perspective view illustrating a process of forming a burying insulating layer 502 according to another embodiment of the inventive concept. Referring to FIGS. 19 and 20, the second apertures 342 are filled with the burying insulating layer 502. The burying insulating layer 502 may be formed by applying an insulating material into the second apertures 342 so that the second apertures 324 are completely filled with the insulating material and panelizes the insulating material, for example, by CMP by using the mask pattern 310 as an etch stopper.

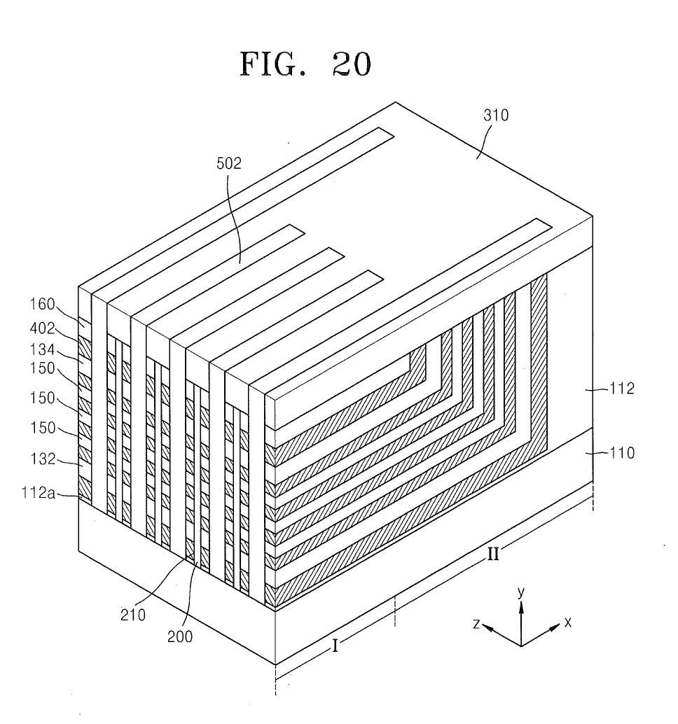

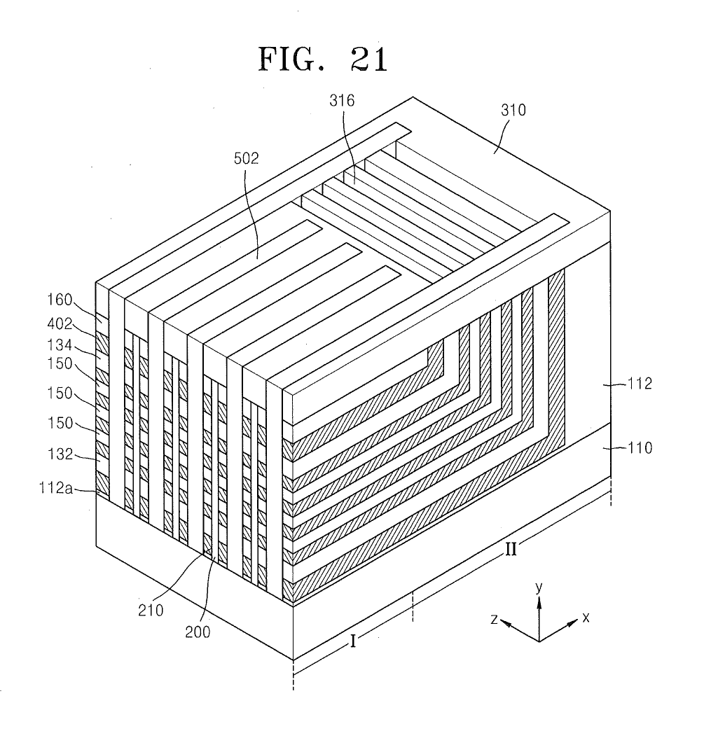

FIG. 21 is a perspective view illustrating a process of forming third apertures 316 according to another embodiment of the inventive concept. Referring to FIGS. 17A, 17B, and 21, the third apertures 316 are formed by partially removing the mask pattern 310 until the supporting insulating layer 140c and the lower supporting insulating layer 122c are exposed. In this case, the third apertures 316 may be formed in such a manner that the lengths thereof are equal to or greater than the distance between the two long spaces 312 in the third direction (z-axis direction) so that not only the supporting insulating layer 140c and the lower supporting insulating layer 122c but also a portion of the conductive layers 402 may be exposed.

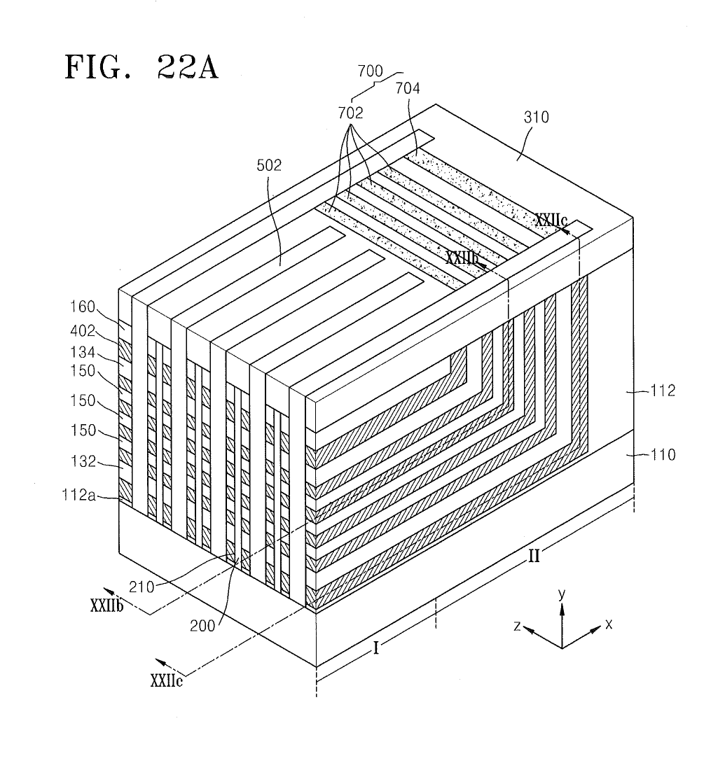

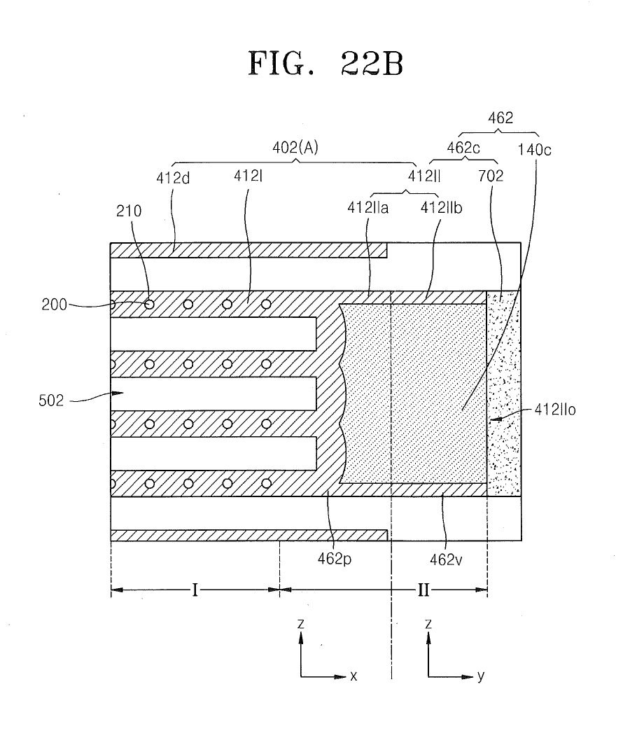

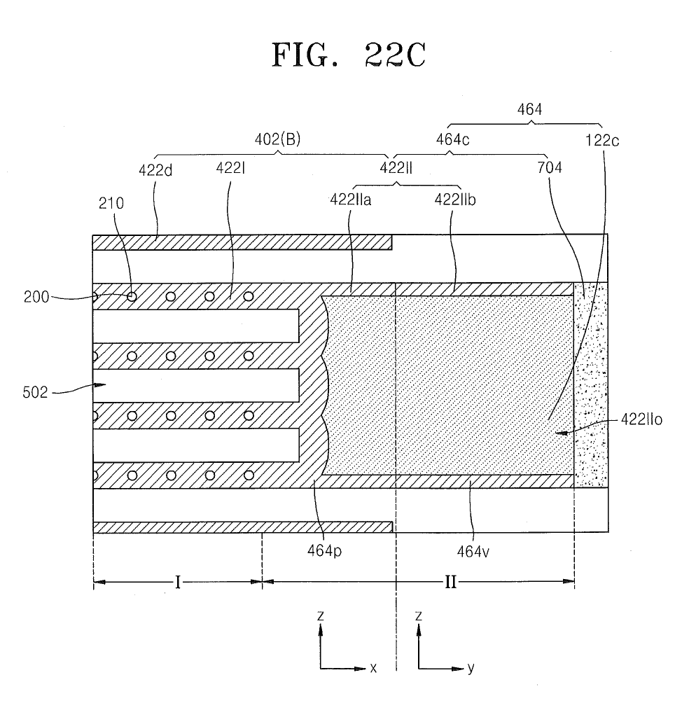

FIGS. 22A to 22C are perspective and cross-sectional views illustrating a process of forming pillar connection units 700 according to another embodiment of the inventive concept. FIG. 22A is a perspective view illustrating the process of forming the pillar connection units 700 according to another embodiment of the inventive concept.

Referring to FIGS. 21 and 22A, the pillar connection units 700 are formed to fill the third apertures 316 therewith. The pillar connection units 700 may be formed by applying a conductive material into the third apertures 316 so that the third apertures 316 may be filled completely with the conductive material and by planarizing the conductive material by using the mask pattern 310 and the burying insulating layer 502 as etch stoppers. From among the pillar connection units 700, portions formed on the supporting insulating layers 140c may be referred to as ‘intermediate pillar connection parts 702’ and the other portion formed on the lower supporting insulating layer 122c may be referred to as a ‘lower pillar connection part 704’. The pillar connection units 700 may be formed of the same material as the conductive layer 402, but embodiments of the inventive concept are not limited thereto.

FIG. 22B is a cross-sectional view illustrating the process of FIG. 22A. In detail, FIG. 22B is a cross-sectional view taken along the line XXIIb-XXIIb of FIG. 22A.

Referring to FIGS. 22A and 22B, a first conductive layer 402(A) includes a gate line 412I formed in the device region I, and a connection conducting part 412II formed in the connection region II. The first conductive layer 402(A) corresponds to portions of the conductive layer 402 that are divided by second insulating layer 150 between the first insulating layer 132 and the third insulating layer 134.

The gate line 412I may extend in the first direction (x-axis direction) while covering surfaces of the semiconductor poles 200 having the gate insulating layer 210 between the gate line 412I and the semiconductor poles 200, and may correspond to the word lines WL1-WLn connected to the gates of the memory cells MC1 to MCn of FIG. 1. There may be a plurality of gate lines 412I disposed apart from one another by the burying insulating layer 502.

The connection conducting part 412II corresponds to portions of the first conductive layer 402(A) formed in the connection region II, and is connected to the plurality of gate line 412I. The plurality of gate lines 412I and the connection conducting part 412II are formed in the spaces from which the second sacrificial layer 140 has been removed and may thus have the same thickness. Also, the connection conducting part 412II includes a horizontal part 412IIa extending in the first direction (x-axis direction), and a vertical pillar part 412IIb that is connected to the horizontal part 412IIa and extends in the second direction (y-axis direction). The intermediate pillar connection parts 702 that extend from the vertical pillar part 412IIb and the supporting insulating layer 140c in the second direction (y-axis direction), constitute the gate connection unit 462c together with the connection conducting unit 412II. Accordingly, the gate connection unit 462c includes the horizontal part 412IIa extending in the first direction (x-axis direction), the vertical pillar part extending in the second direction (y-axis direction), and the intermediate pillar connection parts 702.

Here, a combination of the vertical pillar part 412IIb and the intermediate pillar connection parts 702 may be referred to as a ‘pillar unit 412IIb+702’. The pillar unit 412IIb+702 of FIG. 22B corresponds to and have the functions as the pillar part 410IIb of FIG. 14B.

In the gate connection unit 462c, an aperture or cavity 412IIo is formed in a space defined by the horizontal part 412IIa and the pillar part. The aperture 412IIo may be filled with the supporting insulating layer 140c. One end of the horizontal part 412IIa may be connected to the plurality of gate lines 412I and the other end thereof may be connected to the pillar part 412IIb+702. That is, the horizontal part 412IIa may be disposed between the plurality of gate line 412I connected to one another and the pillar part 412IIb+702.

That is, the portion of the gate connection unit 410II of FIG. 14B, which extends from the aperture 410IIo in the second direction (y-axis direction), is a portion of the first conductive layer 400(A), whereas a portion of the gate connection unit 462c of FIG. 22B corresponding to the portion of the gate connection unit 410II is the intermediate pillar connection part 702 that is formed separate from the first conductive layer 402(A).

The connection conducting part 412II is formed in the space from which the second sacrificial layer 140 of FIG. 6A has been partially removed. Thus, if a plurality of second sacrificial layers 140 are formed, a plurality of connection conducting parts 412II are formed accordingly. The plurality of connection conducting parts 412II may be referred to as a connection conducting part group.

The supporting insulating layer 140c may be disposed in a space corresponding to the aperture 412IIo to retain a space where the connection conducting part 412II is to be formed.

The gate connection unit 462c and the supporting insulating layer 140c may form an L-shaped structure 462 that extends in the third direction (z-axis direction) in the connection region II. The L-shaped structure 462 may be disposed between the first insulating layer 132 and an adjacent second insulating layer 150, between adjacent second insulating layers 150, and between an adjacent second insulating layer 150 and the third insulating layer 134. The L-shaped structure 462 may include a horizontal part 462p extending in the first direction (x-axis direction), and a vertical part 462v extending in the second direction (y-axis direction).

Also, the first conductive layer 402(A) may include a first dummy conductive layer 412d disposed apart from the gate line 412I and the connection conducting part 412II. However, the first dummy conductive layer 412d may not be formed according to a manufacturing method and design.

FIG. 22C is a cross-sectional view illustrating the process of FIG. 22A. In detail, FIG. 22C is a cross-sectional view taken along the line XXIIc-XXIIc of FIG. 22A.

Referring to FIGS. 22A and 22C, a second conductive layer 402(B) includes a lower gate line 422I formed in the device region I, and a lower connection conducting part 422II formed in the connection region II. The second conductive layer 402(B) indicates portions of the conductive layer 402 between the base insulating layer 112a and the first insulating layer 132, and between the insulating pillar 112 and the first insulating layer 132.

The lower gate line 422I extends in the first direction (x-axis direction) while covering surfaces of the semiconductor poles 200 having the gate insulating layer 210 between the lower gate line 422I and the semiconductor poles 200. The lower gate line 422I may thus correspond to the ground selection lines GSL1 and GSL2 connected to the gates of the ground selection transistor GST of FIG. 1. Also, a plurality of lower gate lines 422I may be disposed apart from one another by the burying insulating layer 502.

The lower connection conducting part 422II indicates a portion of the second conductive layer 402(B) formed in the connection region II and is connected to the plurality of lower gate lines 422I. The lower connection conducting part 422II further includes a lower horizontal part 422IIa that extends in the first direction (x-axis direction), and a lower vertical pillar part 422IIb that is connected to the lower horizontal part 422IIa and extends in the second direction (y-axis direction). The lower pillar connection part 704 that extends from the lower vertical pillar part 422IIb and the lower supporting insulating layer 122c in the second direction (y-axis direction), forms a lower gate connection unit 464c together with the lower connection conducting part 422II. Thus, the lower gate connection unit 464c includes the lower horizontal part 422IIa that extends in the first direction (x-axis direction), and the lower vertical pillar part 422IIb and the lower pillar connecting part 704 that extend in the second direction (y-axis direction).

Here, a combination of the lower vertical pillar part 422IIb and the lower pillar connection part 704 may be referred to as a ‘lower pillar unit 422IIb+704’. The lower pillar unit 422IIb+704 of FIG. 22C corresponds to the lower pillar part 420IIb of FIG. 14 and has the same function as the lower pillar part 420IIb of FIG. 14.

In the lower gate connection unit 464c, a lower aperture 422IIo is formed in a space defined by the lower horizontal part 422IIa and the lower pillar unit 422IIb+704. The lower aperture 422IIo may be filled with the lower supporting insulating layer 122c.

That is, the portion of the lower gate connection unit 420II of FIG. 14C, which extends from the lower aperture 420IIo in second direction (y-axis direction), is a portion of the second conductive layer 400(B), whereas lower gate connection unit 464c of FIG. 22C is the lower pillar connection part 704 that is formed separate from the second conductive layer 402(B).

The lower supporting insulating layer 122c may be disposed in a space corresponding to the lower aperture 422IIo so as to retain a space in which the lower connection conducting part 422II is to be formed.

Sides of the lower aperture 422IIo and a plurality of apertures 412IIo, in which the lower supporting insulating layer 122c and the supporting insulating layer 140c, in the second direction (y-axis direction) may be arranged in the first direction (x-axis direction). Similarly, sides of the lower aperture 422IIo and the plurality of apertures 412IIo adjacent to the device region I may be arranged in the second direction (y-axis direction).

The lower gate connection unit 464c and the lower supporting insulating layer 122c may form an L-shaped lower structure 464 that extends in the third direction (z-axis direction) in the connection region II. Spaces between the base insulating layer 112a and the first insulating layer 132, and between the insulating pillar 112 and the first insulating layer 132 may be filled with the L-shaped lower structure 464. The L-shaped lower structure 464 may include a lower horizontal part 464p extending in the first direction (x-axis direction), and a lower vertical part 464v extending in the second direction (y-axis direction).

The second conductive layer 402(B) may further include a second dummy conductive layer 422d disposed apart from the lower gate line 422I and the lower connection conducting part 422II. However, the second dummy conductive layer 422d may not be formed according to a manufacturing method and design.

FIG. 23 is a perspective view illustrating a process of forming contact plugs 602 according to another embodiment of the inventive concept. Referring to FIGS. 22 and 23, the contact plugs 602 are formed on the intermediate pillar connection parts 702 and the lower pillar connection part 704, respectively, so as to connect an external circuit (not shown) to the gate line 412II and the lower gate line 422II, thereby manufacturing the non-volatile memory device 102. The contact plugs 602 may be arranged in a line between the first direction (x-axis direction) and the third direction (z-axis direction) and in a direction that is different from these directions.

Although not shown, an interlevel insulating layer may be formed to fill regions around the contact plugs 602 therewith. In this case, the contact plugs 602 may be formed by forming contact holes in the interlevel insulating layer according to the photolithography process and filling the contact holes with a conductive material.

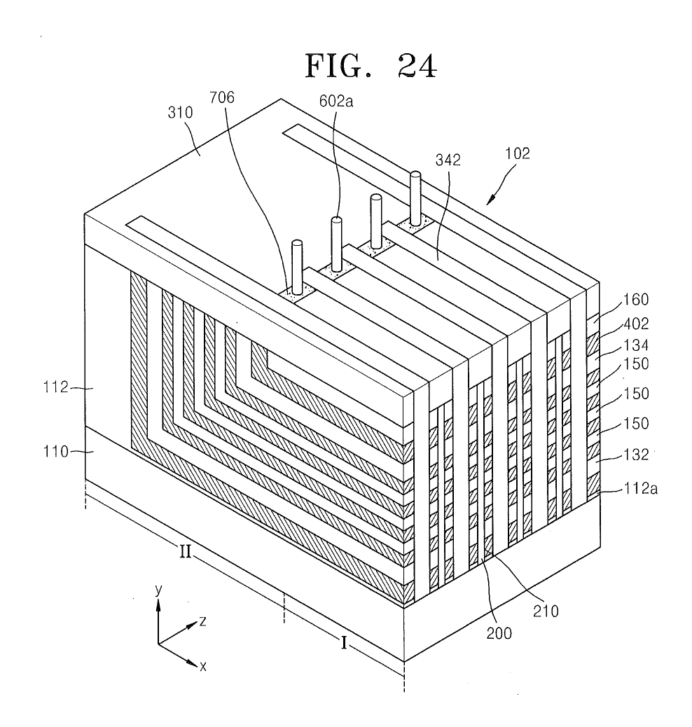

FIG. 24 is a perspective view illustrating a process of forming upper contact plugs 602a according to another embodiment of the inventive concept. In detail, FIG. 24 is a perspective view of a portion of the non-volatile memory device 100, which extends in a direction opposite to the first direction (x-axis direction).

Referring to FIGS. 10, 18A to 18E, 21, 22A, and 24, while the third apertures 316 are formed, the mask pattern 310 is partially removed to expose the conductive layer 402 filling the space from which the third sacrificial layer 124 has been removed. That is, referring to FIG. 18B, an uppermost surface of the conductive layer 402 filling the space from which the third sacrificial layer 124 has been removed is at the same level as an uppermost surface of the cover insulating layer 160 from the substrate 110. Thus, the third apertures 316 may be formed in such a manner that not only the supporting insulating layer 140c and the lower supporting insulating layer 122c but also the conductive layer 402 that fills the space from which the third sacrificial layer 124 has been removed may be exposed. Accordingly, the upper pillar connection part 706 may be formed simultaneously with the pillar connection units 700.

Also, the upper contact plugs 602a may be formed on the upper pillar connection units 706 simultaneously with the contact plugs 602.

FIG. 25 is a schematic block diagram of a non-volatile memory device 800 according to another embodiment of the inventive concept. Referring to FIG. 25, in the non-volatile memory device 800, a NAND cell array 850 may be combined with a core circuit unit 870. For example, the NAND cell array 850 may include the non-volatile memory device 100 of FIGS. 15 and 16 and/or the non-volatile memory device 102 of FIGS. 23 and 24. The core circuit unit 870 may include a control logic unit 871, a row decoder 872, a column decoder 873, a sense amplifier 874, and a page buffer 875.

The control logic unit 871 may communicate with the row decoder 872, the column decoder 873, and the page buffer 875. The row decoder 872 may communicate with the NAND cell array 850 via a plurality of string selection lines SSL, a plurality of word lines WL, and a plurality of ground selection lines GSL. The column decoder 873 may communicate with the NAND cell array 850 via a plurality of bit lines BL. The sense amplifier 874 may be connected to the column decoder 873 when a signal is supplied to the sense amplifier 874 from the NAND cell array 850, and may not be connected to the column decoder 873 when a signal is supplied to the NAND cell array 850 from the sense amplifier 874.

For example, the control logic unit 871 may supply a row address signal to the row decoder 872, and the row decoder 872 may decode the row address signal and supply the result of decoding to the NAND cell array 850 via the plurality of string selection lines SSL, the plurality of word lines WL, and the plurality of ground selection lines GSL. The control logic unit 871 may supply a column address signal to the column decoder 873 or the page buffer 875, and the column decoder 873 may decode the column address signal and supply the result of decoding to the NAND cell array 850 via the bit lines BL. A signal output from the NAND cell array 850 may be supplied to the sense amplifier 874 via the column decoder 873, may be amplified by the sense amplifier 874, and may then be supplied to the control logic unit 871 via the page buffer 875.

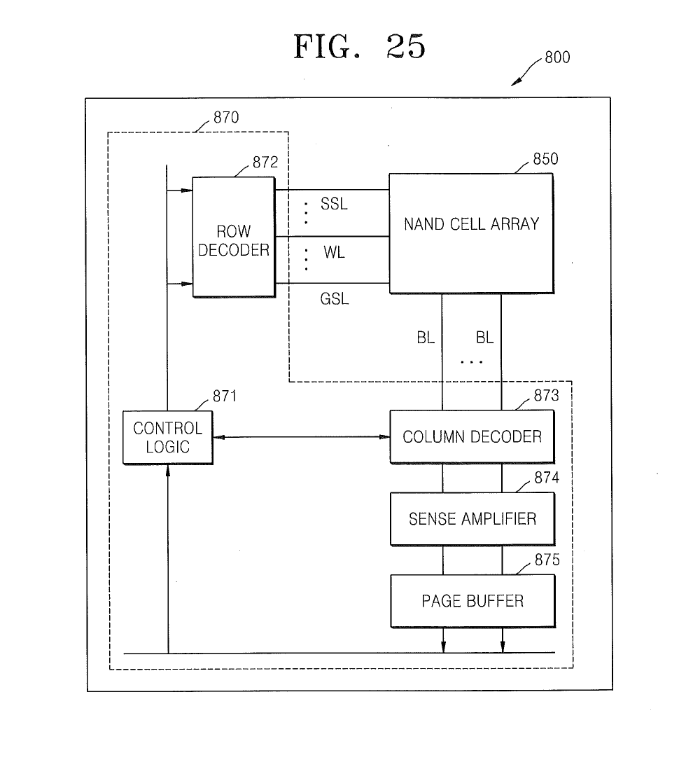

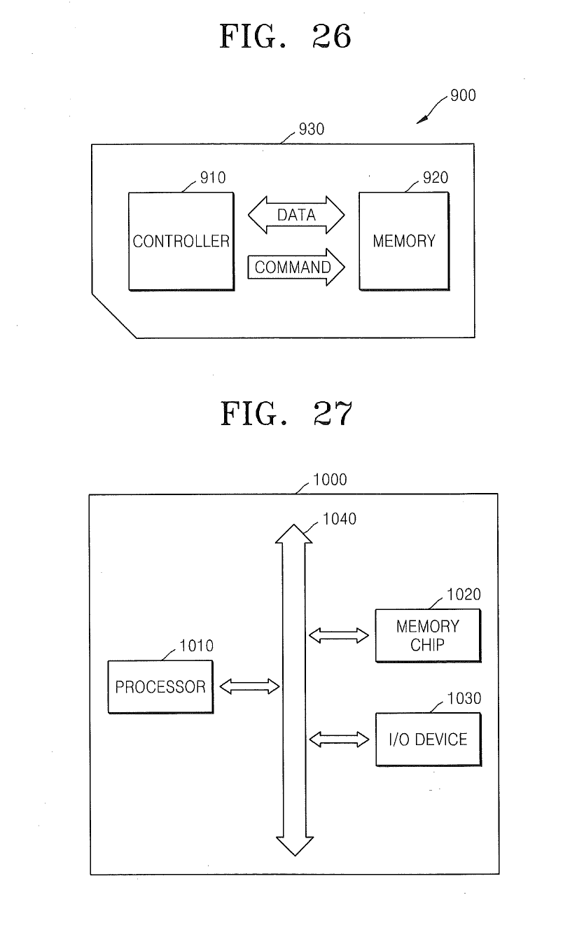

FIG. 26 is a schematic block diagram of a memory card 900 according to an embodiment of the inventive concept. Referring to FIG. 26, the memory card 900 may include a controller 910 and a memory unit 920 that are installed in a housing 930. The controller 910 and the memory unit 920 may exchange an electrical signal with each other. For example, the memory unit 920 and the controller 910 may exchange data with each other according to a command given from the controller 910. Thus, the memory card 900 may store data in the memory unit 920 or may read data from the memory unit 920 and output the data to the outside.

For example, the memory 920 may include the non-volatile memory device 100 of FIGS. 15 and 16 or the non-volatile memory device 102 of FIGS. 23 and 24. The memory card 900 may be used as a data storage medium for various types of portable devices. For example, the memory card 900 may include a multi media card (MMC) or a secure digital card (SD).

FIG. 27 is a schematic block diagram of an electronic system 1000 according to an embodiment of the inventive concept. Referring to FIG. 27, the electronic system 1000 may include a processor 1010, an input/output (I/O) device 1030, and a memory chip 1020. The processor 1010, the I/O device 1030, and the memory chip 1020 may establish data communication with one another via a bus 1040. The processor 1010 may execute a program and may control the electronic system 1000. The I/O device 1030 may be used to input data to or output data from the electronic system 1000. The electronic system 1000 may be connected to an external device (not shown), e.g., a personal computer (PC) or a network, via the I/O device 1030 in order to exchange data with the external device. The memory chip 1020 may store code and data for operating the processor 1010. For example, the memory chip 1020 may include the non-volatile memory device 100 of FIGS. 15 and 16 or the non-volatile memory device 102 of FIGS. 23 and 24.

The electronic system 1000 may be used to manufacture various types of electronic control devices that use the memory chip 1020, for example, a mobile phone, an MP3 player, a navigator, a solid state disk (SSD), and/or a household appliance.

While the inventive concept has been particularly shown and described with reference to exemplary embodiments thereof, it will be understood that various changes in form and details may be made therein without departing from the spirit and scope of the following claims.

1. A memory device, comprising:
a plurality of gate lines extending substantially parallel to one another along a surface of a substrate; and
a connection unit electrically connecting the plurality of gate lines, the connection unit comprising a first portion laterally extending along the surface of the substrate, a second portion extending substantially perpendicular to the surface of the substrate, and a supporting insulating layer extending in a cavity defined by the first and second portions of the connection unit.

2. The device of claim 1, wherein the supporting insulating layer comprises a first portion extending substantially parallel to the surface of the substrate and a second portion extending substantially perpendicular to the surface of the substrate within the cavity.

3. The device of claim 2, further comprising:
a first insulating layer comprising a first portion extending along the surface of the substrate and including the plurality of gate lines and the first portion of the connection unit thereon, and a second portion extending substantially perpendicular to the surface of the substrate and including the second portion of the connection unit on a sidewall thereof; and
a second insulating layer on the plurality of gate lines and the connection unit, the second insulating layer comprising a first portion extending along the plurality of gate lines and the first portion of the connection unit, and a second portion extending substantially perpendicular to the surface of the substrate and along a sidewall of the second portion of the connection unit,
wherein the first and second insulating layers further define the cavity including the supporting insulating layer therein.

4. The device of claim 3, wherein the first and second insulating layers comprise a different material than the supporting insulating layer.

5. The device of claim 3, wherein the substrate comprises a device region including the plurality of gate lines thereon and a connection region including the connection unit thereon adjacent thereto, and further comprising:
a plurality of semiconductor poles extending substantially perpendicular to the surface of the substrate in the device region, wherein each of the plurality of semiconductor poles includes a respective memory cell string comprising a plurality of memory cells extending along a sidewall thereof,
wherein each of the plurality of gate lines extends on the sidewall of a different one of the plurality of semiconductor poles and defines a word line of the respective memory cell string thereon.

6. The device of claim 5, wherein the plurality of gate lines, the connection unit, and the supporting insulating layer respectively comprise a first plurality of gate lines, a first connection unit, and a first supporting insulating layer, and further comprising:
a second plurality of gate lines extending substantially parallel to one another along the first portion of the second insulating layer, wherein each of the second plurality of gate lines extends on a sidewall of a different one of the plurality of semiconductor poles.

7. The device of claim 6, wherein each of the second plurality of gate lines defines a word line of the respective memory cell string, and further comprising:
a second connection unit electrically connecting the second plurality of gate lines, the second connection unit comprising a first portion extending along the first portion of the second insulating layer, a second portion extending along a sidewall of the second portion of the second insulating layer substantially perpendicular to the surface of the substrate, and a second supporting insulating layer extending in a cavity defined by the first and second portions of the second connection unit.

8. The device of claim 7, wherein the first supporting insulating layer and the second supporting insulating layer comprise a same material.

9. The device of claim 6, wherein each of the second plurality of gate lines defines a string select line of the respective memory cell string, and further comprising:
a cover insulating layer on the second plurality of gate lines,
wherein a surface of the cover insulating layer is below an uppermost surface of the second portion of the first insulating layer.

10. The device of claim 3, wherein a thickness of the second portion of the first insulating layer is greater than that of the second portion of the second insulating layer, and wherein a thickness of the first portion of the first insulating layer is less than that of the first portion of the second insulating layer

11. The device of claim 1, wherein the first and second portions of the connection unit comprise different materials.

12.-15. (canceled)

16. A non-volatile memory device comprising:
a substrate including a main surface extending in a first direction, wherein a device region and a connection region are defined in the substrate;
a plurality of semiconductor poles extending in a second direction substantially perpendicular to the first direction in the device region;
a plurality of NAND cell strings extending along sidewalls of the plurality of semiconductor poles, where each of the plurality of NAND cell strings includes a plurality of memory cells;
a plurality of gate lines defining word lines of the plurality of memory cells and extending in the first direction in the device region; and
a gate connection structure including a plurality of conductive gate connection units in the connection region, where each of the plurality of conductive gate connection units includes a horizontal part connected to the plurality of gate lines and extending in the first direction, and a pillar part connected to the horizontal part and extending in the second direction,
wherein each of the plurality of gate connection units includes an aperture that is formed in a space defined by the corresponding horizontal part and pillar part, wherein the aperture includes a supporting insulating layer therein.

17. The non-volatile memory device of claim 16, wherein upper and lower surfaces of the supporting insulating layer are at same levels as upper and lower surfaces of the plurality of gate connection units, respectively.

18. The non-volatile memory device of claim 16, further comprising:
a first interlevel insulating layer between the plurality of gate connection units,
wherein the first interlevel insulating layer is formed of a different material than that of the supporting insulating layer.

19. The non-volatile memory device of claim 16, wherein each of the plurality of NAND cell strings further comprises:
a lower selection transistor and an upper selection transistor having the plurality of memory cells therebetween; and
a plurality of lower gate lines forming the lower selection transistor and extending in the first direction; and
a lower gate connection unit in the connection region and formed of a conductive material, the lower gate connection unit including a lower horizontal part that is connected to the plurality of lower gate lines and extends in the first direction, and a lower pillar part that is connected to the lower horizontal part and extends in the second direction,
wherein the lower gate connection unit comprises a lower aperture formed in a space defined by the lower horizontal part and the lower pillar part, and including a lower supporting insulating layer in the lower aperture.

20. The non-volatile memory device of claim 19, wherein the supporting insulating layer and the lower supporting insulating layer are formed of the same material.

21. The non-volatile memory device of claim 19, further comprising:
a plurality of upper gate lines forming the upper selection transistor and extending in the first direction; and
a plurality of upper gate connection units formed of a conductive material in the connection region and connected to the plurality of upper gate lines, respectively,
wherein each of the plurality of upper gate connection units comprises an upper horizontal part extending in the first direction, and an upper pillar part connected to the upper horizontal part and extending in the second direction.

22. The non-volatile memory device of claim 21, further comprising:
a second interlevel insulating layer between the plurality of upper gate connection units and the gate connection unit group, and
wherein a second thickness of the second interlevel insulating layer along the first direction is greater than a first thickness of the first interlevel insulating layer along the first direction.

23. The non-volatile memory device of claim 22, further comprising:
a third interlevel insulating layer between the lower gate connection unit and the gate connection structure, and
wherein a third thickness of the third interlevel insulating layer along a direction opposite to the first direction is less than the second thickness of the second interlevel insulating layer.

24. The non-volatile memory device of claim 18, further comprising:
a fourth interlevel insulating layer between gate lines forming the memory cells of a NAND cell string selected from among the plurality of NAND cell strings, and
wherein the first interlevel insulating layer and the fourth interlevel insulating layer are formed of the same material.

25. The non-volatile memory device of claim 16, wherein the plurality of gate connection units are connected to ones of the plurality of gate lines at a same level with respect to the substrate.
